(19) United States
(12) Patent Application Publication
(10) Pub. No.: US 2026/0040941 A1
(43) Pub. Date: Feb. 5, 2026

(54) THREE-DIMENSIONAL MEMORY DEVICE WITH BIT LINES LOCATED IN DIFFERENT VERTICAL LEVELS AND METHOD OF MAKING THE SAME

(71) Applicant: SANDISK TECHNOLOGIES LLC, ADDISON, TX (US)

(72) Inventors: Kota FUNAYAMA, Yokkaichi (JP); Masaaki HIGASHITANI, Cupertino, CA (US)

(21) Appl. No.: 18/791,823

(22) Filed: Aug. 1, 2024

(51) Int. Cl. H01L 23/532; G11C 16/04; H01L 23/522; H01L 23/528; H10B 41/10; H10B 41/27; H10B 41/35; H10B 43/10; H10B 43/27; H10B 43/35

(52) U.S. Cl. CPC H01L 23/53295; G11C 16/0483; H01L 23/5226; H01L 23/5283; H10B 41/10; H10B 41/27; H10B 41/35; H10B 43/10; H10B 43/27; H10B 43/35

(57) ABSTRACT

A semiconductor structure includes a three dimensional memory device containing drain regions having top surfaces in a first horizontal plane, first bit lines electrically connected to a first subset of the drain regions, and second bit lines electrically connected to a second subset of the drain regions. The second bit lines are located above the first bit lines.

### FIELD

The present disclosure relates generally to the field of semiconductor devices, and particularly to a three-dimensional memory device with bit lines located in different vertical levels and methods for forming the same.

### BACKGROUND

Flash memory devices include NAND and NOR memory devices. Such memory devices may be formed by sequentially depositing memory device layers over a driver circuit located on a silicon wafer.

### SUMMARY

According to an aspect of the present disclosure, a semiconductor structure includes a three dimensional memory device containing drain regions having top surfaces in a first horizontal plane, first bit lines electrically connected to a first subset of the drain regions, and second bit lines electrically connected to a second subset of the drain regions. The second bit lines are located above the first bit lines.

According to another aspect of the present disclosure, a method of forming a semiconductor structure comprises: providing a first memory die that comprises first alternating stacks of first insulating layers and first electrically conductive layers, first memory openings vertically extending through the first alternating stacks, first memory opening fill structures located in the first memory openings, and first bit lines, wherein the first alternating stacks are laterally spaced apart from each other by first lateral isolation trenches that laterally extend along a first horizontal direction, wherein each of the first memory opening fill structures comprises a respective first vertical semiconductor channel, a respective vertical stack of first memory elements, and a respective first drain region contacting a first end of the respective first vertical semiconductor channel, wherein the first electrically conductive layers comprise first word lines of the first memory elements of the first memory opening fill structures, and wherein the first bit lines extend over each of the first alternating stacks along a second horizontal direction that is perpendicular to the first horizontal direction, are electrically connected to a respective first subset of the first drain regions, are vertically spaced by a first vertical distance from a first horizontal plane including top surfaces of the first drain regions, and have a uniform pitch p along the first horizontal direction; providing an additional semiconductor die that comprises second bit lines having a pitch that equals the uniform pitch p; and bonding the additional semiconductor die to the first memory die such that the second bit lines extend over the first bit lines along the second horizontal direction, are electrically connected to a respective second subset of the first drain regions, are vertically spaced by a second vertical distance that is greater than the first vertical distance from the first horizontal plane, and have the uniform pitch p along the first horizontal direction.

According to yet another aspect of the present disclosure, a method of forming a semiconductor structure comprises: forming an assembly of first alternating stacks of first insulating layers and first electrically conductive layers and first memory opening fill structures vertically extending through the first alternating stacks, wherein the first alternating stacks are laterally spaced apart from each other by first lateral isolation trenches that laterally extend along a first horizontal direction, wherein each of the first memory opening fill structures comprises a respective first vertical semiconductor channel, a respective vertical stack of first memory elements, and a respective first drain region contacting a first end of the respective first vertical semiconductor channel, and wherein the first electrically conductive layers comprise first word lines of the first memory elements of the first memory opening fill structures; forming first bit lines extending over each of the first alternating stacks along a second horizontal direction that is perpendicular to the first horizontal direction, wherein the first bit lines are electrically connected to a respective first subset of the first drain regions, are vertically spaced by a first vertical distance from a first horizontal plane including top surfaces of the first drain regions, and have a uniform pitch p along the first horizontal direction; and forming second bit lines extending over the first bit lines along the second horizontal direction, wherein the second bit lines are electrically connected to a respective second subset of the first drain regions, are vertically spaced by a second vertical distance that is greater than the first vertical distance from the first horizontal plane, and have the uniform pitch p along the first horizontal direction.

### BRIEF DESCRIPTION OF THE DRAWINGS

FIG. 1 is a vertical cross-sectional view of a first exemplary structure after formation of a first-tier alternating stack, first stepped surfaces, and a first-tier stepped dielectric material portion according to a first embodiment of the present disclosure.

FIG. 2A is a vertical cross-sectional view of the first exemplary structure after formation of first-tier memory openings and first-tier support openings according to the first embodiment of the present disclosure. FIG. 2B is a top-down view of the first exemplary structure of FIG. 2A. The hinged vertical plane A-A′ is the cut plane of the vertical cross-sectional view of FIG. 2A.

FIG. 3 is a vertical cross-sectional view of the first exemplary structure after formation of first sacrificial opening fill structures according to the first embodiment of the present disclosure.

FIG. 4 is a vertical cross-sectional view of the first exemplary structure after formation of a second-tier alternating stack, a second-tier stepped dielectric material portion, second-tier memory openings, second-tier support openings, and second sacrificial opening fill structures according to the first embodiment of the present disclosure.

FIG. 5 is a vertical cross-sectional view of the first exemplary structure after formation of support pillar structures according to the first embodiment of the present disclosure.

FIG. 6 is a vertical cross-sectional view of the first exemplary structure after formation of inter-tier memory openings according to the first embodiment of the present disclosure.

FIGS. 7A-7E are sequential vertical cross-sectional views of a memory opening during formation of a memory opening fill structure according to an embodiments of the present disclosure.

FIG. 8A is a schematic vertical cross-sectional view of the first exemplary structure after formation of memory opening fill structures according to the first embodiment of the present disclosure. FIG. 8B is a top-down view of the first exemplary structure of FIG. 8A. The vertical plane A-A is the cut plane of the vertical cross-sectional view of FIG. 8A.

FIG. 9A is a vertical cross-sectional view of the first exemplary structure after formation of lateral isolation trenches according to the first embodiment of the present disclosure. FIG. 9B is a top-down view of the first exemplary structure of FIG. 9A. The vertical plane A-A is the cut plane of the vertical cross-sectional view of FIG. 9A.

FIG. 10 is a vertical cross-sectional view of the first exemplary structure after formation of laterally-extending cavities according to the first embodiment of the present disclosure.

FIG. 11A is a schematic vertical cross-sectional view of the first exemplary structure after formation of electrically conductive layers according to the first embodiment of the present disclosure. FIG. 11B is a magnified view of a region of the first exemplary structure of FIG. 11A around a memory opening fill structure.

FIG. 12A is a schematic vertical cross-sectional view of the first exemplary structure after formation of lateral isolation trench fill structures, layer contact via structures, drain contact via structures, and through-memory-level connection via structures according to the first embodiment of the present disclosure. FIG. 12B is a top-down view of the first exemplary structure of FIG. 12A. The vertical plane A-A is the cut plane of the vertical cross-sectional view of FIG. 12A.

FIG. 13A is a schematic vertical cross-sectional view of the first exemplary structure after formation of first connection via structures, first bit lines, and first-bit-line-level interconnect structures according to the first embodiment of the present disclosure.

FIG. 13B is a top-down view of the first exemplary structure of FIG. 13A. The vertical plane A-A is the cut plane of the vertical cross-sectional view of FIG. 13A.

FIG. 14A is a schematic vertical cross-sectional view of the first exemplary structure after formation of second connection via structures, second bit lines, and second-bit-line-level interconnect structures according to the first embodiment of the present disclosure.

FIG. 14B is a top-down view of the first exemplary structure of FIG. 14A. The vertical plane A-A is the cut plane of the vertical cross-sectional view of FIG. 14A.

FIG. 15 is a vertical cross-sectional view of the first exemplary structure after formation of memory-die dielectric material layers embedding memory-die metal interconnect structures and memory-die bonding pads to provide a memory die according to the first embodiment of the present disclosure.

FIG. 16 is a vertical cross-sectional view of a logic die according to the first embodiment of the present disclosure.

FIG. 17 is a vertical cross-sectional view of the first exemplary structure after attaching the logic die to the memory die according to the first embodiment of the present disclosure.

FIG. 18 is a vertical cross-sectional view of the first exemplary structure after removal of the carrier substrate according to the first embodiment of the present disclosure.

FIG. 19 is a vertical cross-sectional view of the first exemplary structure after formation of backside contact pads according to the first embodiment of the present disclosure.

FIG. 20A is a first vertical cross-sectional view of a first alternative embodiment of the first exemplary structure along a first vertical plane that cuts through a first subset of the first connection via structures according to the first embodiment of the present disclosure.

FIG. 20B is a second vertical cross-sectional view of the first alternative embodiment of the first exemplary structure along a second vertical plane that cuts through a second subset of the first connection via structures according to the first embodiment of the present disclosure.

FIG. 20C is a plan view of the first alternative embodiment of the first exemplary structure illustrated in FIGS. 20A and 20B. The vertical plane A-A′ is the cut plane of the vertical cross-sectional view of FIG. 20A. The vertical plane B-B′ is the cut plate of the vertical cross-sectional view of FIG. 20B.

FIG. 21A is a first vertical cross-sectional view of a second alternative embodiment of the first exemplary structure along a first vertical plane that cuts through a subset of the first connection via structures according to the first embodiment of the present disclosure.

FIG. 21B is a second vertical cross-sectional view of the second alternative embodiment of the first exemplary structure along a second vertical plane that cuts through another subset of the first connection via structures according to the first embodiment of the present disclosure.

FIG. 22 is a vertical cross-sectional view of a second exemplary structure after formation of a backside insulating layer embedding backside metal interconnect structures and a source layer according to a second embodiment of the present disclosure.

FIG. 23A is a vertical cross-sectional view of the second exemplary structure after formation of an assembly of alternating stacks of insulating layers and electrically conductive layers, memory opening fill structures, and a stepped dielectric material portion according to the second embodiment of the present disclosure. FIG. 23B is a vertical cross-sectional view of a region of the second exemplary structure of FIG. 23A around a memory opening fill structure.

FIG. 24A is a first vertical cross-sectional view of the second exemplary structure after formation of a first memory die according to the second embodiment of the present disclosure. FIG. 24B is a second vertical cross-sectional view of the second exemplary structure (that is offset along the bit line direction from the first cross-sectional view) after formation of the first memory die according to the second embodiment of the present disclosure.

FIG. 25A is a first vertical cross-sectional view of a second memory die according to the second embodiment of the present disclosure. FIG. 25B is a second vertical cross-sectional view (that is offset along the bit line direction from the first cross-sectional view) of the second memory die according to the second embodiment of the present disclosure.

FIG. 26 is a vertical cross-sectional view of the second exemplary structure after bonding the second memory die to the first memory die according to the second embodiment of the present disclosure.

FIG. 27 is a vertical cross-sectional view of the second exemplary structure after removing a substrate of the first memory die according to the second embodiment of the present disclosure.

FIG. 28 is a vertical cross-sectional view of the second exemplary structure after bonding a logic die to the backside of the first memory die according to the second embodiment of the present disclosure.

FIG. 29 is a vertical cross-sectional view of the second exemplary structure after formation of backside contact structures on the second memory die according to the second embodiment of the present disclosure.

FIG. 30A is a plan view of selected structural elements within the first memory die 900A in the second exemplary structure of FIG. 29 according to the second embodiment of the present disclosure. FIG. 30B is a plan view of selected structural elements within the second memory die 900B in the second exemplary structure of FIG. 29 according to the second embodiment of the present disclosure. FIG. 30C is a first vertical cross-sectional view of the second exemplary structure of FIG. 29 along the vertical plane C-C′ in FIGS. 30A and 30B, which is a first vertical plane that cuts through a first subset of the first connection via structures 98A. FIG. 30D is a second vertical cross-sectional view of the second exemplary structure of FIG. 29 along the vertical plane D-D′ in FIGS. 30A and 30B, which is a second vertical plane that cuts through a second subset of the first connection via structures. FIG. 30E is a magnified view of a bonding interface 800 region in the vertical cross-sectional view of the second exemplary structure shown in FIG. 30C. FIG. 30F is a magnified view of a bonding interface 800 region in the vertical cross-sectional view of the second exemplary structure shown in FIG. 30D. FIG. 30G is a third vertical cross-sectional view of the second exemplary structure of FIG. 29 along the vertical plane G-G′ in FIG. 29.

### DETAILED DESCRIPTION

As memory devices shrink, the pitch between adjacent bit lines also shrink. A small bit line pitch increases the capacitance between laterally adjacent bit lines, reducing device performance. As discussed above, the embodiments of the present disclosure are directed to a three-dimensional memory device with bit lines located in different vertical levels for increasing the effective bit line pitch between laterally adjacent bit lines and methods for forming the same, the various aspects of which are described below. Embodiments of the disclosure can be employed to form various semiconductor structures such as a bonded assembly of a memory die and a logic die. In one embodiment, the vertically offset bit lines may be vertically located in different bonded memory dies between upper and lower semiconductor channels located in the respective memory dies. This reduces the channel height, which improves the device cell current and reduces wafer and die warpage.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1×10⁻⁵ S/m to 1×10⁵ S/m. As used herein, a “semiconductor material” refers to a material having electrical conductivity in the range from 1×10⁻⁵ S/m to 1 S/m in the absence of electrical dopants therein, and is capable of producing a doped material having electrical conductivity in a range from 1 S/m to 1×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1×10⁵ S/m. As used herein, an “insulator material” or a “dielectric material” refers to a material having electrical conductivity less than 1×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1×10⁻⁵ S/m to 1×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

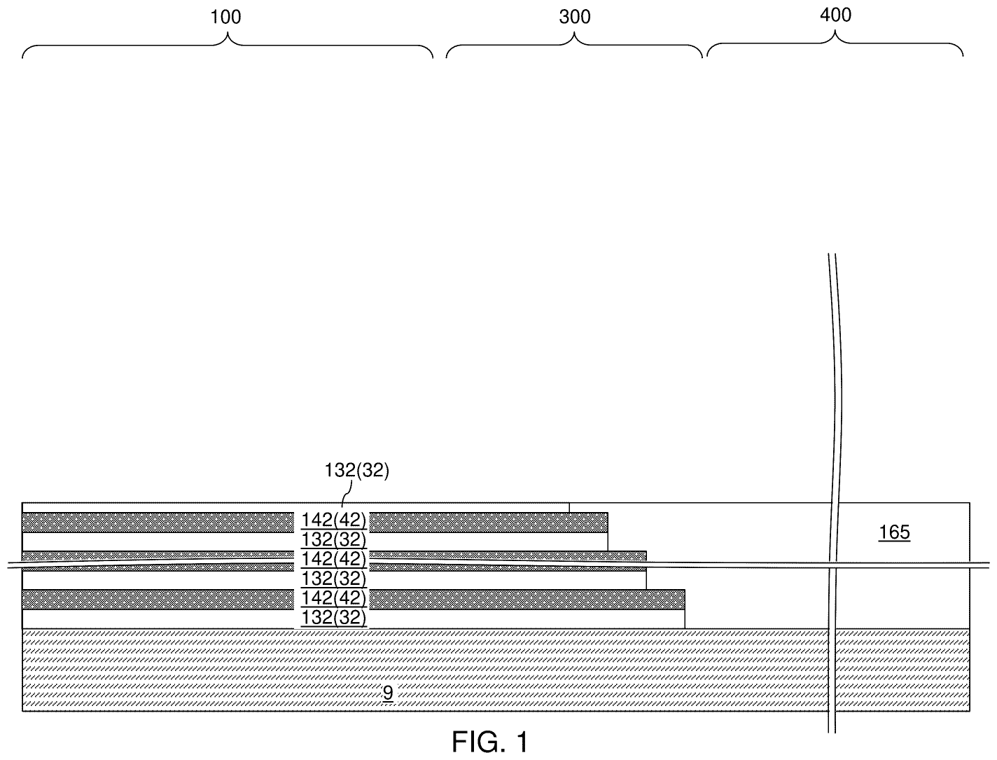

Referring to FIG. 1, a first exemplary structure according to a first embodiment of the present disclosure is illustrated. The first exemplary structure comprises a substrate 9, which may be a semiconductor substrate or a conductive substrate. In one embodiment, the substrate 9 may be a carrier substrate that is subsequently removed. For example, the substrate 9 may comprise a commercially available silicon wafer.

A first alternating stack of insulating layers 32 and spacer material layers can be formed over the substrate 9. The spacer material layers may be formed as sacrificial material layers 42. In case a second alternating stack of additional insulating layers and additional spacer material layers is subsequently formed over the first alternating stack to form a multi-tier structure, the first alternating stack is referred to as a first-tier alternating stack, and the second alternating stack is referred to as a second-tier alternating stack. In this case, the insulating layers 32 within the first-tier alternating stack are herein referred to as first insulating layers 132, and spacer material layers (such as the sacrificial material layers 42) within the first-tier alternating stack are herein referred to as first spacer material layers (such as first sacrificial material layers 142).

The first insulating layers 132 comprise an insulating material such as undoped silicate glass or a doped silicate glass, and the first sacrificial material layers 142 comprise a sacrificial material such as silicon nitride or a silicon-germanium alloy. In one embodiment, the first insulating layers 132 may comprise silicon oxide layers, and the first sacrificial material layers 142 may comprise silicon nitride layers. The first-tier alternating stack (132, 142) may comprise multiple repetitions of a unit layer stack including a first insulating layer 132 and a first sacrificial material layer 142. The total number of repetitions of the unit layer stack within the first-tier alternating stack (132, 142) may be, for example, in a range from 8 to 1,024, such as from 32 to 256, although lesser and greater number of repetitions may also be employed.

Each of the first insulating layers 132 may have a thickness in a range from 20 nm to 100 nm, such as from 30 nm to 60 nm, although lesser and greater thicknesses may also be employed. Each of the first sacrificial material layers 142 may have a thickness in a range from 20 nm to 100 nm, such as from 30 nm to 60 nm, although lesser and greater thicknesses may also be employed. The first exemplary structure comprises a memory array region 100 in which a three-dimensional array of memory elements is to be subsequently formed, and a contact region 300 in which layer contact via structures contacting word lines are to be subsequently formed.

While an embodiment is described in which the first spacer material layers are formed as first sacrificial material layers 142, the first spacer material layers may be formed as first electrically conductive layers in an alternative embodiment. In this case, processing steps performed to replace the first sacrificial material layers 142 with first electrically conductive layers may be omitted. Generally, spacer material layers may be formed as or may be subsequently replaced with electrically conductive layers.

Optional stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A first stepped cavity is formed within the volume from which portions of the first-tier alternating stack (132, 142) are removed through formation of the stepped surfaces. A “stepped cavity” refers to a cavity having stepped surfaces.

The first stepped cavity can have various stepped surfaces such that the horizontal cross-sectional shape of the first stepped cavity changes in steps as a function of the vertical distance from the top surface of the substrate 9. In one embodiment, the first stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each first sacrificial material layer 142 other than a topmost first sacrificial material layer 142 within the alternating stack (132, 142) laterally extends farther than any overlying first sacrificial material layer 142 within the first-tier alternating stack (132, 142) in the terrace region. The stepped surfaces of the first-tier alternating stack (132, 142) continuously extend from a bottommost layer within the first-tier alternating stack (132, 142) to a topmost layer within the first-tier alternating stack (132, 142).

A first stepped dielectric material portion 165 (i.e., an insulating fill material portion) can be formed in the first stepped cavity by deposition of a dielectric material therein. For example, a dielectric material such as silicon oxide can be deposited in the stepped cavity. Excess portions of the deposited dielectric material can be removed from above the top surface of the topmost layer of the first-tier alternating stack (132, 142), for example, by chemical mechanical planarization (CMP). The remaining portion of the deposited dielectric material filling the first stepped cavity constitutes the first stepped dielectric material portion 165. As used herein, a “stepped” element refers to an element that has stepped surfaces and a horizontal cross-sectional area that increases or decreases stepwise as a function of a vertical distance from a top surface of a substrate on which the element is present. If silicon oxide is employed for the first stepped dielectric material portion 165, the silicon oxide of the first stepped dielectric material portion 165 may, or may not, be doped with dopants such as B, P, and/or F.

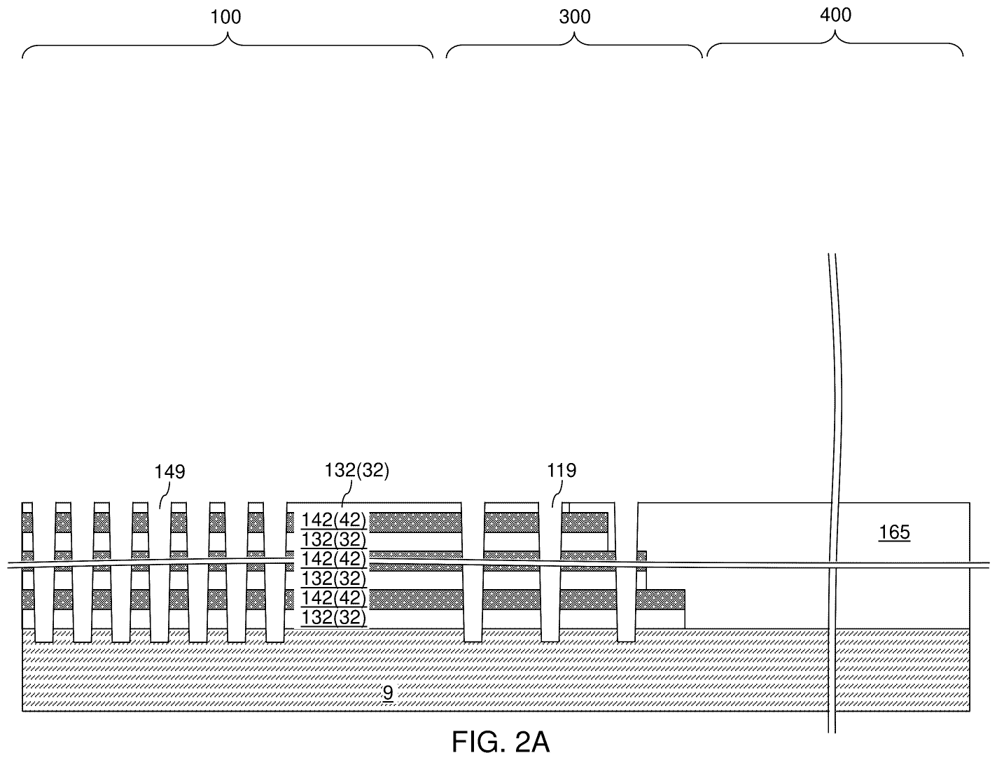

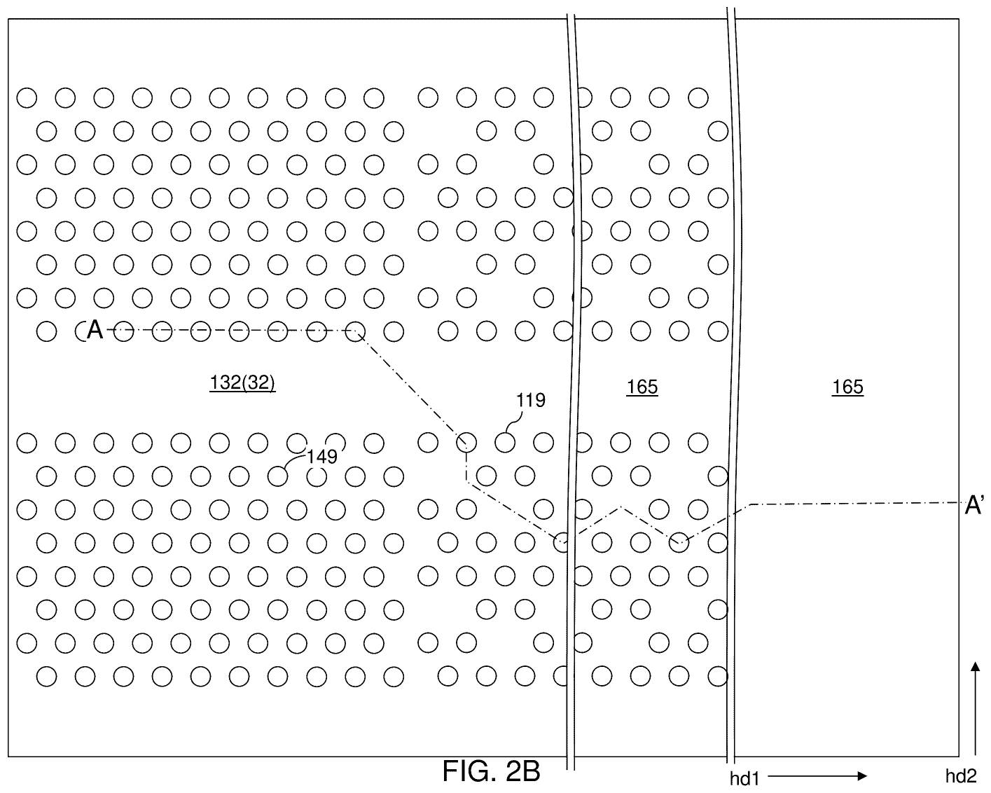

Referring to FIGS. 2A and 2B, a first etch mask layer (such as a photoresist layer) can be formed over the first-tier alternating stack (132, 142), and can be lithographically patterned to form openings therein. A first anisotropic etch process can be performed to transfer the pattern of the openings in the first etch mask layer through the first stepped dielectric material portion 165, and the first-tier alternating stack (132, 142), and into the substrate 9. First-tier memory openings 149 can be formed through the first-tier alternating stack (132, 142) in the memory array region 100, and first-tier support openings 119 can be formed through the first stepped dielectric material portion 165 and the first-tier alternating stack (132, 142) in the contact region 300. Each of the first-tier memory openings 149 and the first-tier support openings 119 can vertically extend into the substrate 9. In one embodiment, bottom surfaces of the first-tier memory openings 149 and the first-tier support openings 119 may be formed within the lower source-level semiconductor layer 112. The first-tier memory openings 149 and the first-tier support openings 119 may have a diameter in a range from 40 nm to 400 nm, such as from 80 nm to 200 nm, although lesser and greater thicknesses may be employed. The first etch mask layer can be removed, for example, by ashing after the first anisotropic etch process.

The first-tier memory openings 149 may be formed as clusters of first-tier memory openings 149. Each cluster of first-tier memory openings 149 may comprise an area of a memory block containing a plurality of rows of memory openings 49. Each row of first-tier memory openings 149 may comprise a plurality of first-tier memory openings 149 that are arranged along the first horizontal direction hd1 (which may be a word line direction) with a uniform pitch. The rows of first-tier memory openings 149 may be laterally spaced from each other along the second horizontal direction hd2 (which may be a bit line direction), which may be perpendicular to the first horizontal direction hd1. In one embodiment, each cluster of first-tier memory openings 149 may be formed as a two-dimensional periodic array of first-tier memory openings 149.

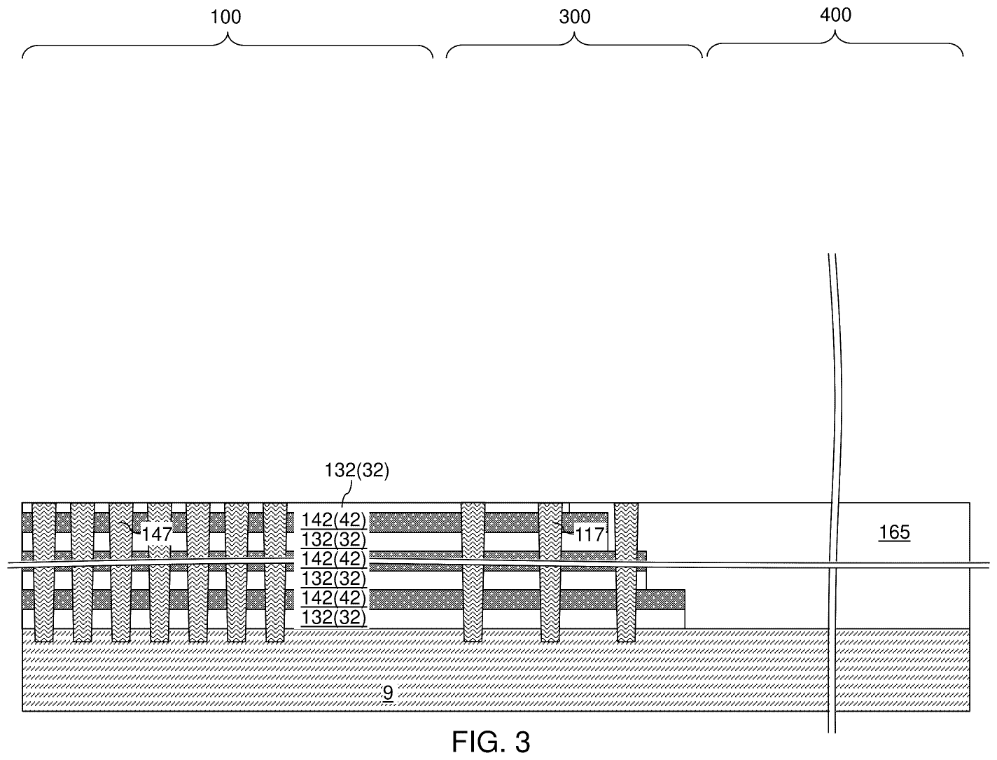

Referring to FIG. 3, a first sacrificial fill material, such as a carbon-based material (e.g., amorphous carbon, diamond-like carbon, or a doped carbon material), a high etch-rate dielectric material (e.g., borosilicate glass or organosilicate glass), or a polymer material, can be deposited in the first-tier memory openings 149 and in the first-tier support openings 119 by a conformal deposition process. Excess portions of the first sacrificial fill material can be removed from above the top surface of the first-tier alternating stack (132, 142), for example, by a recess etch process. Each remaining portion of the first sacrificial fill material that fills a respective first-tier memory opening 149 constitutes a first sacrificial memory opening fill structure 147. Each remaining portion of the first sacrificial fill material that fills a respective first-tier support opening 119 constitutes a first sacrificial support opening fill structure 117.

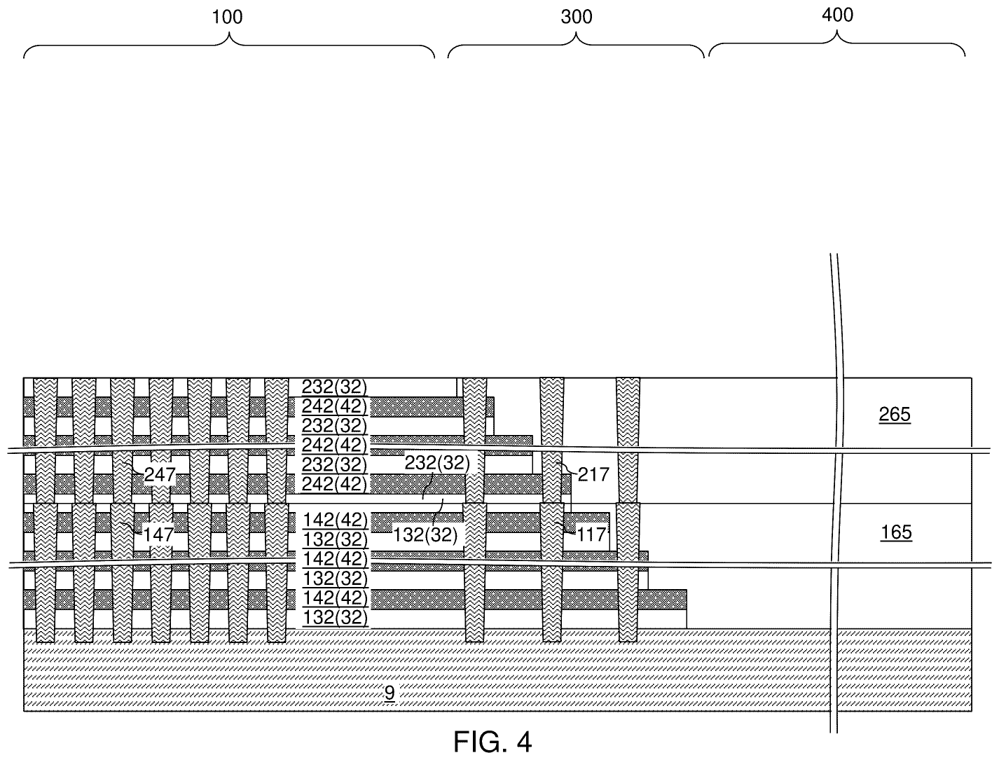

Referring to FIG. 4, a second-tier alternating stack (232, 242) of second insulating layers 232 and second spacer material layers may be formed above the first-tier alternating stack (132, 142) and the first stepped dielectric material portion 165. The second insulating layers 232 can be additional insulating layers 32 having a same material composition and a same thickness range as the first insulating layers 132. The second spacer material layers can be additional spacer material layers having a same material composition and a same thickness range as the first spacer material layers in the first-tier alternating stack (132, 142). In one embodiment, the second spacer material layers may comprise second sacrificial material layers 242. In this case, the second sacrificial material layers 242 can be additional sacrificial material layers 42 having a same material composition and a same thickness range as the first sacrificial material layers 142.

The second-tier alternating stack (232, 242) may comprise multiple repetitions of a unit layer stack including a second insulating layer 232 and a second sacrificial material layer 242. The total number of repetitions of the unit layer stack within the second-tier alternating stack (232, 242) may be, for example, in a range from 8 to 1,024, such as from 32 to 256, although lesser and greater number of repetitions may also be employed. Each of the second insulating layers 232 may have a thickness in a range from 20 nm to 100 nm, such as from 30 nm to 60 nm, although lesser and greater thicknesses may also be employed. Each of the second sacrificial material layers 242 may have a thickness in a range from 20 nm to 100 nm, such as from 30 nm to 60 nm, although lesser and greater thicknesses may also be employed.

The first-tier alternating stack (132, 142) and the second-tier alternating stack (232, 242) are collectively referred to as an alternating stack (32, 42) of insulating layers 32 and sacrificial material layers 42.

While an embodiment is described in which the second spacer material layers are formed as second sacrificial material layers 242, the second spacer material layers may be formed as second electrically conductive layers in an alternative embodiment. In this case, processing steps performed to replace the second sacrificial material layers 242 with second electrically conductive layers may be omitted.

Optional stepped surfaces are formed in the contact region 300 by patterning the second-tier alternating stack (232, 242). The stepped surfaces of the second-tier alternating stack (232, 242) may be laterally offset toward the memory array region 100 relative to the stepped surfaces of the first-tier alternating stack (132, 142) in a plan view. A second stepped cavity is formed within the volume from which portions of the second-tier alternating stack (232, 242) are removed through formation of the stepped surfaces. A “stepped cavity” refers to a cavity having stepped surfaces.

The second stepped cavity can have various stepped surfaces such that the horizontal cross-sectional shape of the second stepped cavity changes in steps as a function of the vertical distance from the top surface of the substrate 9. In one embodiment, the second stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type.

Each second sacrificial material layer 242 other than a topmost second sacrificial material layer 242 within the alternating stack (232, 242) laterally extends farther than any overlying second sacrificial material layer 242 within the second-tier alternating stack (232, 242) in the terrace region. The stepped surfaces of the second-tier alternating stack (232, 242) continuously extend from a bottommost layer within the second-tier alternating stack (232, 242) to a topmost layer within the second-tier alternating stack (232, 242).

A second stepped dielectric material portion 265 (i.e., an insulating fill material portion) can be formed in the second stepped cavity by deposition of a dielectric material therein. For example, a dielectric material such as silicon oxide can be deposited in the stepped cavity. Excess portions of the deposited dielectric material can be removed from above the top surface of the topmost layer of the second-tier alternating stack (232, 242), for example, by chemical mechanical planarization (CMP). The remaining portion of the deposited dielectric material filling the second stepped cavity constitutes the second stepped dielectric material portion 265. If silicon oxide is employed for the second stepped dielectric material portion 265, the silicon oxide of the second stepped dielectric material portion 265 may, or may not, be doped with dopants such as B, P, and/or F. The combination of the first stepped dielectric material portion 165 and the second stepped dielectric material portion 265 may be collectively referred to as stepped dielectric material portions 65.

A second etch mask layer (such as a photoresist layer) can be formed over the second-tier alternating stack (232, 242), and can be lithographically patterned to form openings therein. A second anisotropic etch process can be performed to transfer the pattern of the openings in the second etch mask layer through the second stepped dielectric material portion 265 and the second-tier alternating stack (232, 242). Second-tier memory openings can be formed through the second-tier alternating stack (232, 242) directly on a top surface of a respective first sacrificial memory opening fill structure 147 in the memory array region 100. Second-tier support openings can be formed through the second stepped dielectric material portion 265 and the second-tier alternating stack (232, 242) directly on a top surface of a respective first sacrificial support opening fill structure 117 in the contact region 300. Each of the second-tier memory openings and the second-tier support openings may have about the same diameter as the diameter of a respective underlying first sacrificial opening fill structure (147, 117). The second etch mask layer can be removed, for example, by ashing after the second anisotropic etch process.

A second sacrificial fill material, such as a carbon-based material (e.g., amorphous carbon, diamond-like carbon, or a doped carbon material), a high etch-rate dielectric material (e.g., borosilicate glass or organosilicate glass), or a polymer material, can be deposited in the second-tier memory openings and in the second-tier support openings by a conformal deposition process. Excess portions of the second sacrificial fill material can be removed from above the top surface of the second-tier alternating stack (232, 242), for example, by a recess etch process. Each remaining portion of the second sacrificial fill material that fills a respective second-tier memory opening constitutes a second sacrificial memory opening fill structure 247. Each remaining portion of the second sacrificial fill material that fills a respective second-tier support opening constitutes a second sacrificial support opening fill structure 217.

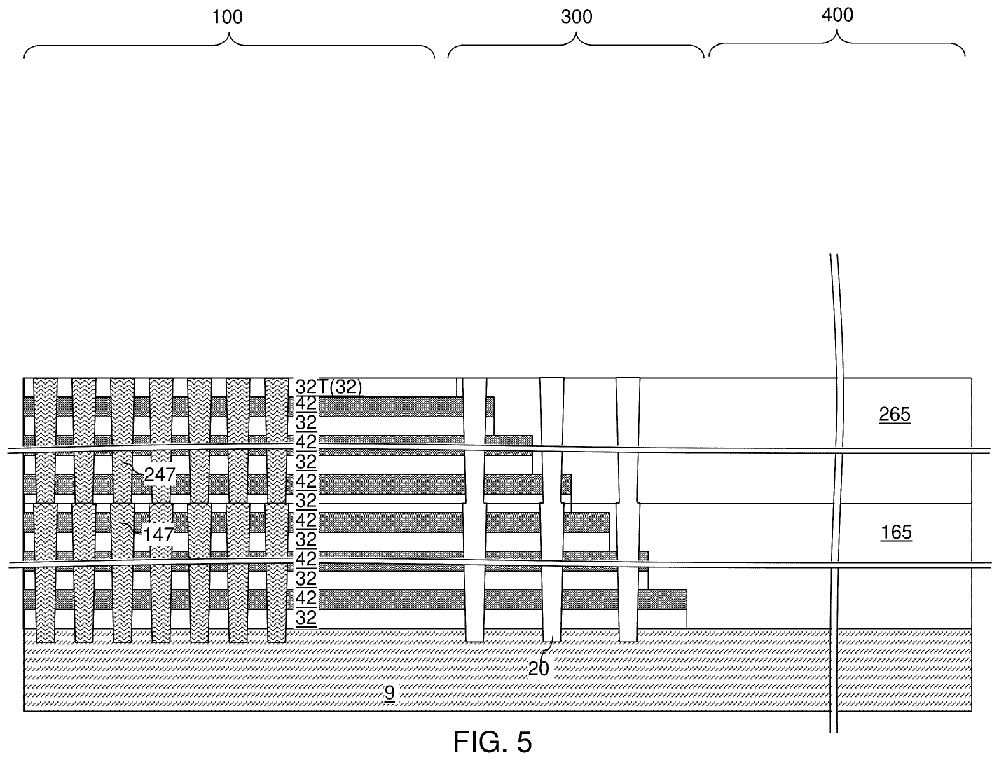

Referring to FIG. 5, a sacrificial mask layer (not shown) is formed over the memory array region 100. The exposed first and second sacrificial support opening fill structures (117, 217) in the contact region 300 are removed by selective etching or ashing to reopen the first-tier and second-tier support openings. A dielectric material, such as silicon oxide is deposited in the first-tier and second-tier support openings to form support pillar structures 20. The sacrificial mask layer is then removed by selective etching or ashing.

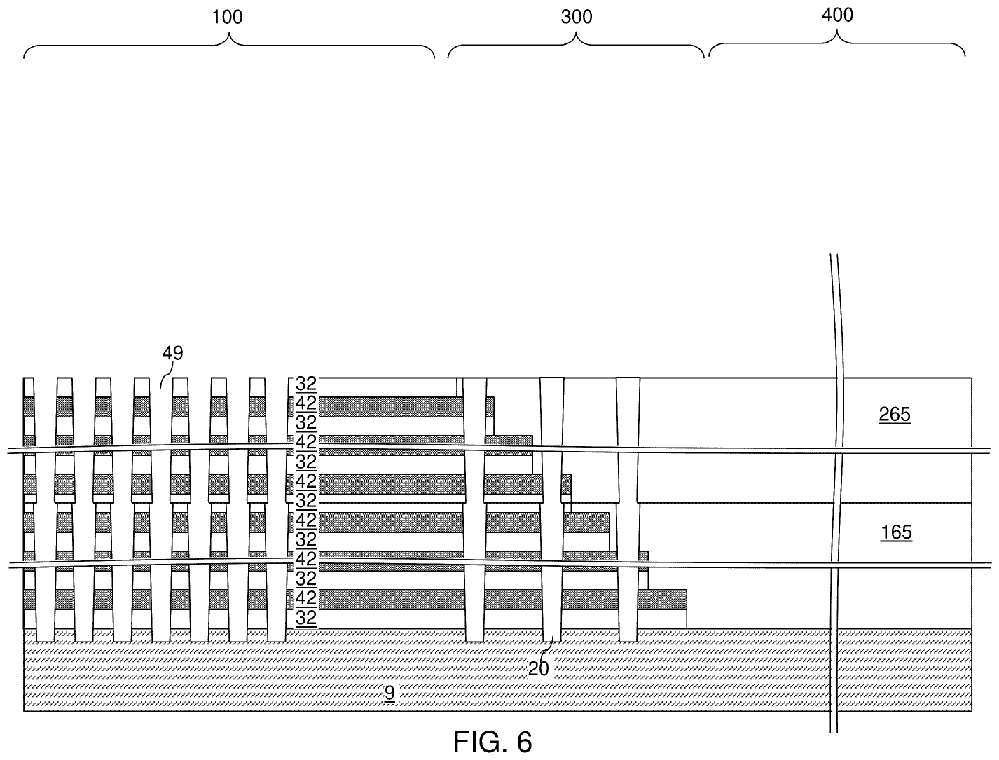

Referring to FIG. 6, the sacrificial memory opening fill structures (147, 247) in the memory array region 100 can be removed selective to the materials of the stepped dielectric material portions 65, the support pillar structures 20, and the alternating stack (32, 42). For example, an selective etch process or an ashing process may be employed to remove the sacrificial memory opening fill structures and portions of the optional etch stop liner in the memory array region 100. Voids are formed in the volumes of the memory openings 49.

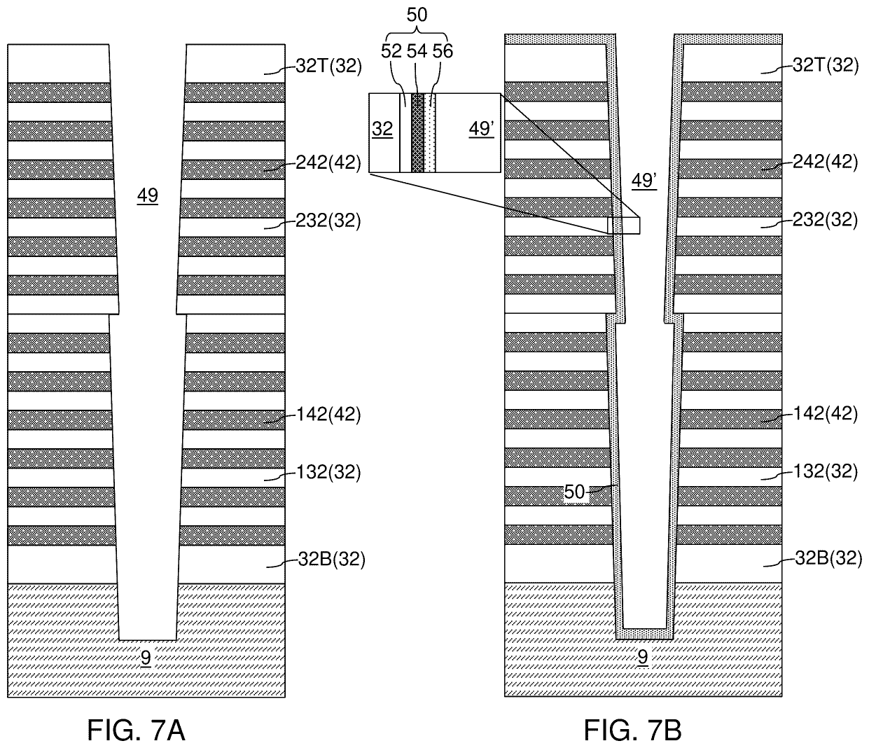

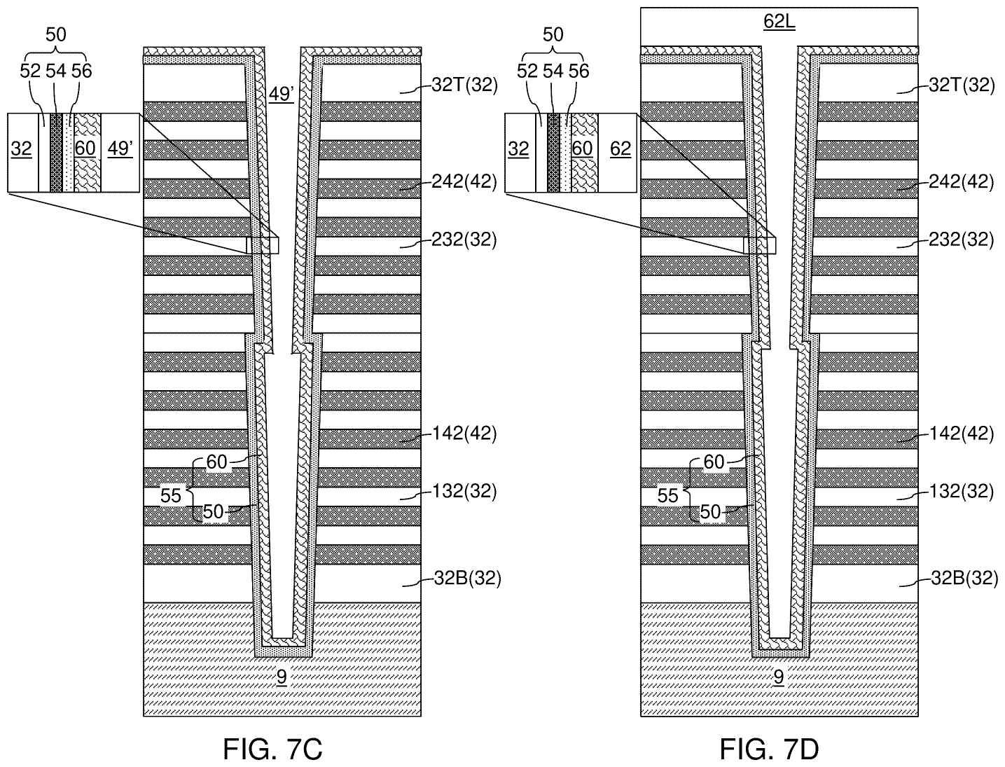

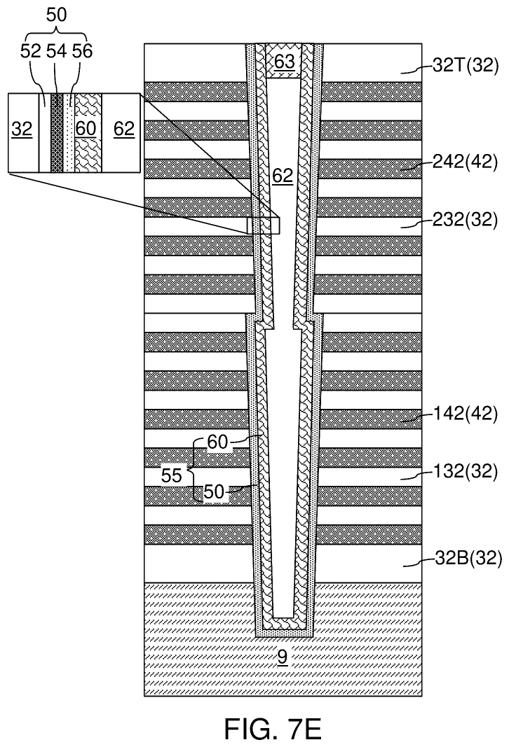

FIGS. 7A-7E are sequential vertical cross-sectional views of a memory opening 49 during formation of a memory opening fill structure 58.

Referring to FIG. 7A, a memory opening 49 is illustrated after the processing steps of FIG. 6. Each memory opening 49 vertically extends through each layer within the alternating stack (32, 42). The bottommost layer of the alternating stack (32, 42) may be a bottommost insulating layer 32B, and the topmost layer of the alternating stack (32, 42) may be a topmost insulating layer 32T.

Referring to FIG. 7B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprises a charge storage material, the optional dielectric liner 56 may comprise a tunneling dielectric layer. A memory cavity 49′ is present in an unfilled volume of the memory opening 49.

Referring to FIG. 7C, a semiconductor channel material layer 60L can be deposited over each memory film 50 by performing a conformal deposition process. If the semiconductor channel material layer 60L is doped, the semiconductor channel material layer 60L may have a doping of a first conductivity type, which may be p-type or n-type. The thickness of the semiconductor channel material layer 60L may be in a range from 5 nm to 50 nm, such as from 10 nm to 30 nm, although lesser and greater thicknesses may also be employed.

Referring to FIG. 7D, a dielectric core layer 62L comprising a dielectric fill material, such as silicon oxide, can be deposited in remaining volumes of the memory openings 49. While the dielectric core layer 62L can be deposited employing a conformal deposition process, such as a chemical vapor deposition process, the conformity of the conformal deposition process may not be perfect. Thus, the thickness of a bottom portion of the dielectric core layer 62L at the bottom of each memory opening 49 may be less than the thickness of an upper portion of the dielectric core layer 62L at the top of each memory opening 49.

Referring to FIG. 7E, the dielectric core layer 62L can be vertically recessed such that each remaining portion of the dielectric core layer has a top surface at, or about, the horizontal plane including the bottom surface of the topmost insulating layers 32. Each remaining portion of the dielectric core layer constitutes a dielectric core 62. A doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5×10¹⁸/cm³ to 2×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42, or generally speaking, at levels of spacer material layers that may be formed as, or may be subsequently replaced at least partly with, electrically conductive layers.

In the alternative embodiment, the support pillar structures 20 may be formed in the support openings at the same time as the memory opening fill structures 58 are formed in the memory openings 49. In this case, the support pillar structures 20 comprise the same materials as the memory opening fill structures 58.

An anneal process can be performed to activate electrical dopants in the drain region 63 and in the vertical semiconductor channel 60. In this case, any amorphous semiconductor material in the vertical semiconductor channel 60 is converted into a polycrystalline semiconductor material. In one embodiment, grains within the vertical semiconductor channel 60 may extends predominantly along long a respective local direction that is perpendicular to a respective proximal portion of an inner sidewall of the vertical semiconductor channel 60 and perpendicular to a respective proximal portion of an outer sidewall of the vertical semiconductor channel 60. As used herein, the grains extend predominantly along a specific direction if more than 50% of the drains extend along the specific direction.

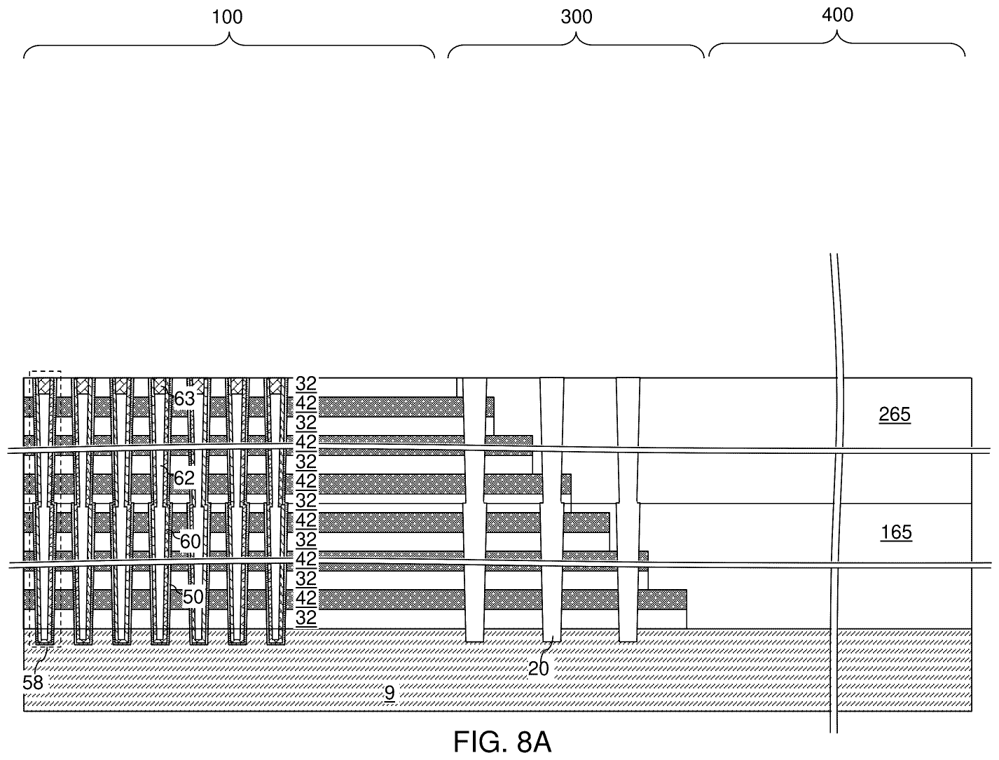

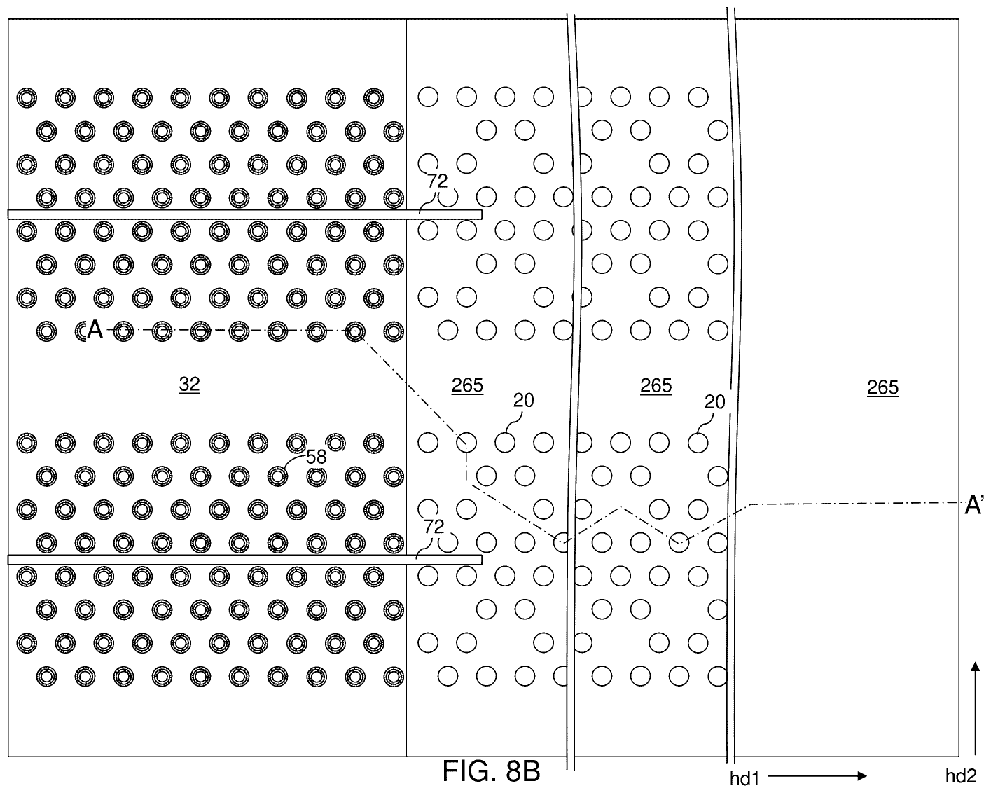

Referring to FIGS. 8A and 8B, the first exemplary structure is illustrated after formation of memory opening fill structures 58 within the memory openings 49. The memory opening fill structures 58 are located in the memory openings 49. Each of the memory opening fill structures 58 comprises a respective vertical semiconductor channel 60, a respective vertical stack of memory elements (which may comprise portions of a memory material layer 54) located at levels of the sacrificial material layers 42, and a respective drain region 63 contacting a first end of the respective vertical semiconductor channel 60.

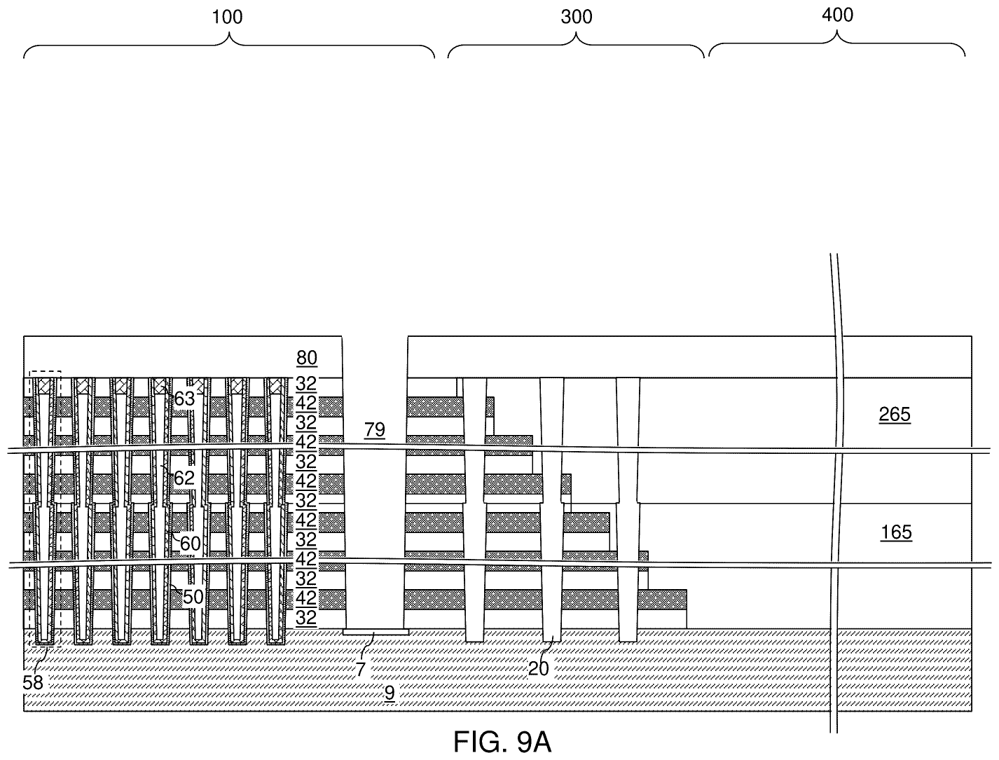

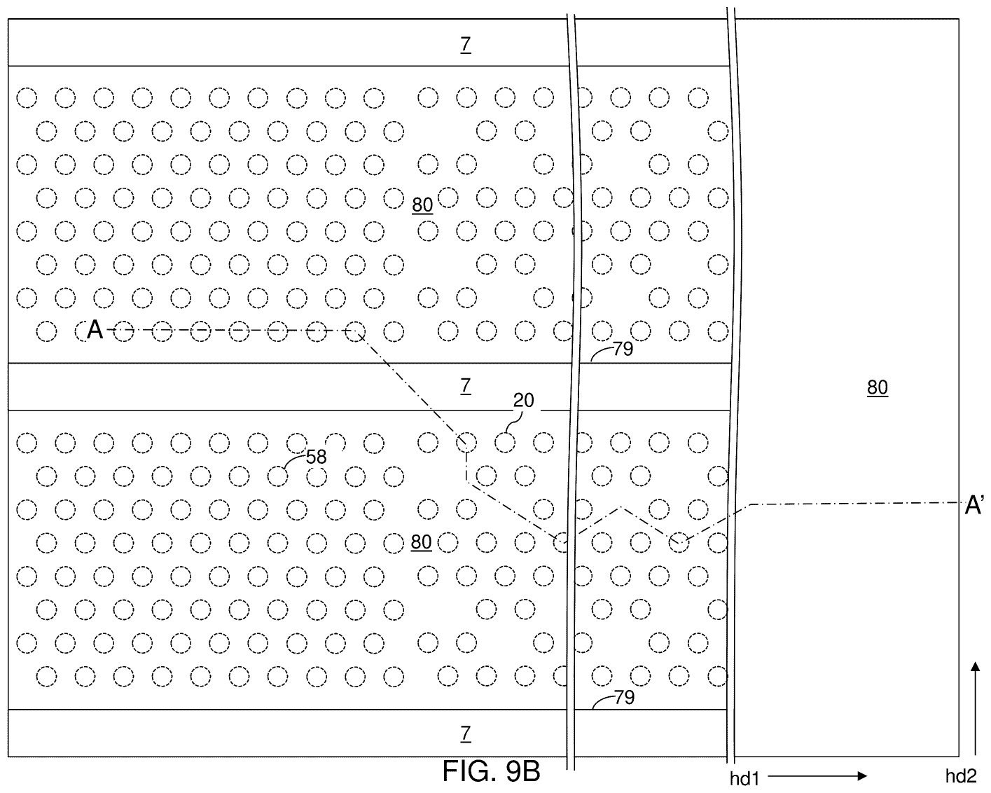

Referring to FIGS. 9A and 9B, a dielectric material, such as undoped silicate glass (i.e., silicon oxide) or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), and the stepped dielectric material portions 65, and into the substrate 9. Lateral isolation trenches 79 laterally extending along the first horizontal direction hd1 can be formed through the alternating stack (32, 42), the stepped dielectric material portions 65, and the contact-level dielectric layer 80. Each of the lateral isolation trenches 79 may comprise a respective pair of lengthwise sidewalls that are parallel to the first horizontal direction hd1 and vertically extend from the top surface of the contact-level dielectric layer 80 to a surface of the source-level sacrificial layer 104. A surface of the source-level sacrificial layer 104 can be physically exposed underneath each lateral isolation trench 79. The photoresist layer can be subsequently removed, for example, by ashing.

An oxidation process can be performed to convert physically exposed surface portions of the substrate 9 into semiconductor oxide liners 7. The thickness of the semiconductor oxide liners 7 may be in a range from 5 nm to 20 nm, although lesser and greater thicknesses may also be employed.

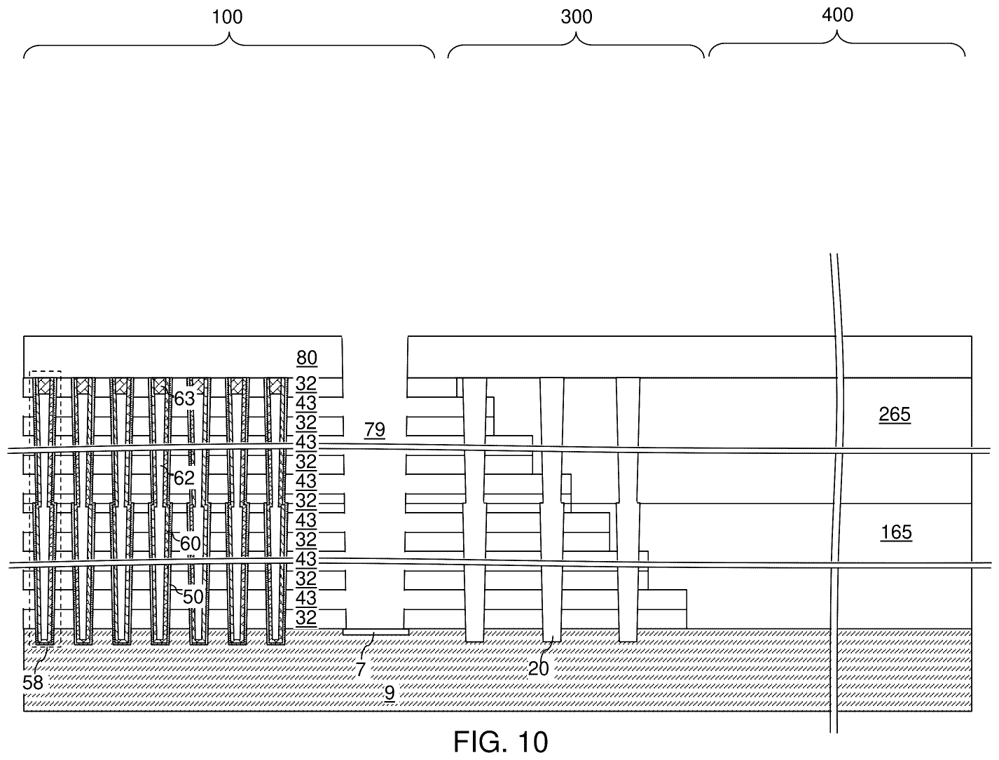

Referring to FIG. 10, an etchant that selectively etches the material of the sacrificial material layers 42 with respect to the material of the insulating layers 32 and the semiconductor oxide liner 7 can be introduced into the lateral isolation trenches 79, for example, employing an isotropic etch process. Lateral recesses 43 are formed in volumes from which the sacrificial material layers 42 are removed. The removal of the sacrificial material layers 42 can be selective to the materials of the insulating layers 32, the stepped dielectric material portions 65, and the material of the outermost layer of the memory films 50. In one embodiment, the sacrificial material layers 42 can include silicon nitride, and the materials of the insulating layers 32 and the stepped dielectric material portions 65 can include silicon oxide.

The etch process that removes the second material selective to the first material and the outermost layer of the memory films 50 can be a wet etch process employing a wet etch solution, or can be a gas phase (dry) etch process in which the etchant is introduced in a vapor phase into the lateral isolation trenches 79. For example, if the sacrificial material layers 42 include silicon nitride, the etch process can be a wet etch process in which the first exemplary structure is immersed within a wet etch tank including phosphoric acid, which etches silicon nitride selective to silicon oxide, silicon, and various other materials employed in the art. The support pillar structure 20, the stepped dielectric material portions 65, and the memory stack structures 55 provide structural support while the lateral recesses 43 are present within volumes previously occupied by the sacrificial material layers 42.

Each lateral recess 43 can be a laterally extending cavity having a lateral dimension that is greater than the vertical extent of the cavity. In other words, the lateral dimension of each lateral recess 43 can be greater than the height of the lateral recess 43. A plurality of lateral recesses 43 can be formed in the volumes from which the second material of the sacrificial material layers 42 is removed. The memory openings in which the memory stack structures 55 are formed are herein referred to as front side openings or front side cavities in contrast with the lateral recesses 43.

Each of the plurality of lateral recesses 43 can extend substantially parallel to the top surface of the substrate 9. A lateral recess 43 can be vertically bounded by a top surface of an underlying insulating layer 32 and a bottom surface of an overlying insulating layer 32. In one embodiment, each lateral recess 43 can have a uniform height throughout.

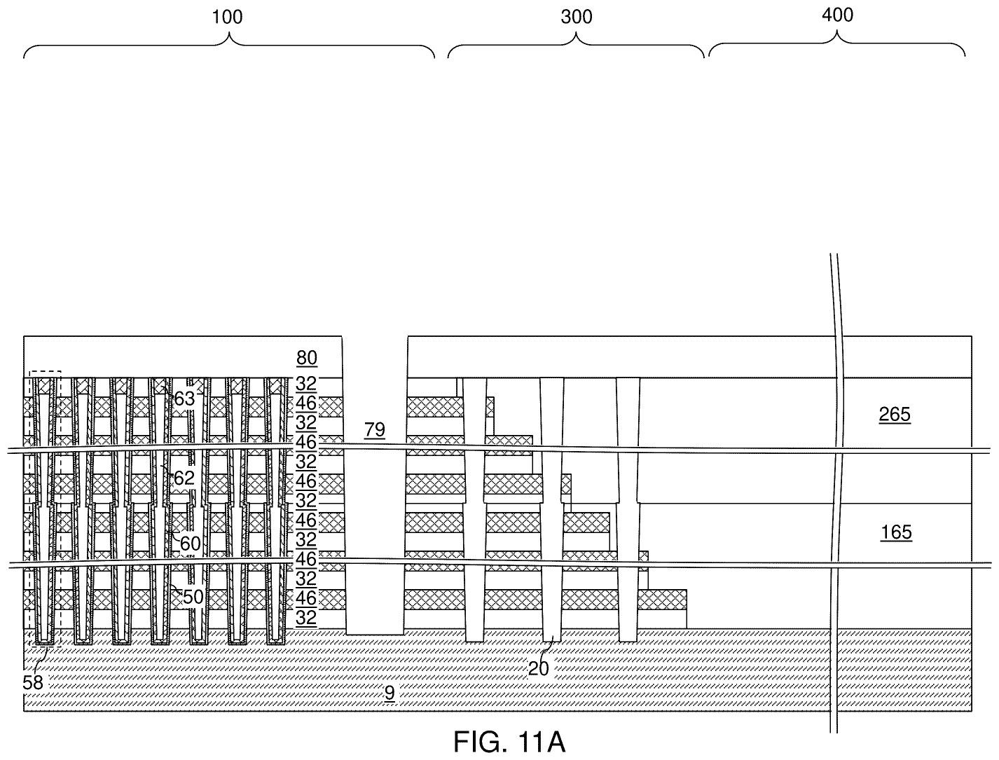

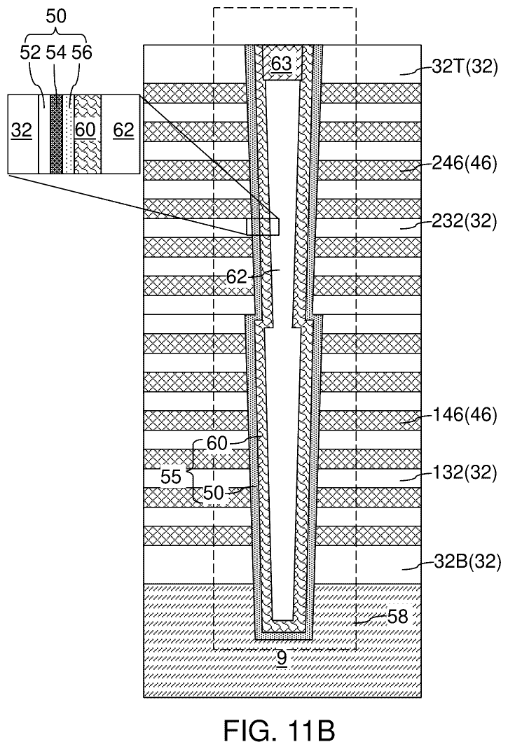

Referring to FIG. 11, an outer blocking dielectric layer (not expressly illustrated) can be optionally formed. The outer blocking dielectric layer, if present, comprises a dielectric material that functions as a control gate dielectric for the control gates to be subsequently formed in the lateral recesses 43. In case the blocking dielectric layer 52 is present within each memory opening, the outer blocking dielectric layer is optional. In case the blocking dielectric layer 52 is omitted, the outer blocking dielectric layer is present.

At least one conductive material can be deposited in the lateral recesses 43 by providing at least one reactant gas into the lateral recesses 43 through the lateral isolation trenches 79. A metallic barrier layer can be deposited in the lateral recesses 43. The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

A metal fill material is deposited in the plurality of lateral recesses 43, on the sidewalls of the at least one lateral isolation trench 79, and over the top surface of the contact-level dielectric layer 80 to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas such as WF₆. In one embodiment, the metallic fill material layer can be a tungsten layer including a residual level of fluorine atoms as impurities. The metallic fill material layer is spaced from the insulating layers 32 and the memory stack structures 55 by the metallic barrier layer, which is a metallic barrier layer that blocks diffusion of fluorine atoms therethrough.

A plurality of electrically conductive layers 46 can be formed in the plurality of lateral recesses 43, and a continuous metallic material layer can be formed on the sidewalls of each lateral isolation trench 79 and over the contact-level dielectric layer 80. Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the lateral isolation trenches 79 or above the contact-level dielectric layer 80.

The deposited metallic material of the continuous electrically conductive material layer is etched back from the sidewalls of each lateral isolation trench 79 and from above the contact-level dielectric layer 80 by performing an isotropic etch process that etches the at least one conductive material of the continuous electrically conductive material layer. Each remaining portion of the deposited metallic material in the lateral recesses 43 constitutes an electrically conductive layer 46. Each electrically conductive layer 46 can be a conductive line structure.

Thus, the sacrificial material layers 42 are replaced with the electrically conductive layers 46. Generally, the electrically conductive layers 46 can be formed by providing a metallic precursor gas into the lateral isolation trenches 79 and into the lateral recesses 43.

At least one uppermost electrically conductive layer 46 may comprise a drain side select gate electrode. At least one bottommost electrically conductive layer 46 may comprise a source side select gate electrode. The remaining electrically conductive layers 46 may comprise word lines. Each word line functions as a common control gate electrode for the plurality of vertical NAND strings (e.g., memory opening fill structures 58).

Generally, a memory device can be formed, which comprises an alternating stack (32, 46) of insulating layers 32 and electrically conductive layers 46, memory openings 49 vertically extending through the alternating stack (32, 46), and memory opening fill structures 58 located in the memory openings 49. Each of the memory opening fill structures 58 comprises a respective vertical semiconductor channel 60, a respective vertical stack of memory elements (which may comprise portions of a memory material layer 54) located at levels of the sacrificial material layers 42, and a respective drain region 63 contacting a first end of the respective vertical semiconductor channel 60. The electrically conductive layers 46 comprise select gate electrodes and word lines of the respective vertical stack of memory elements.

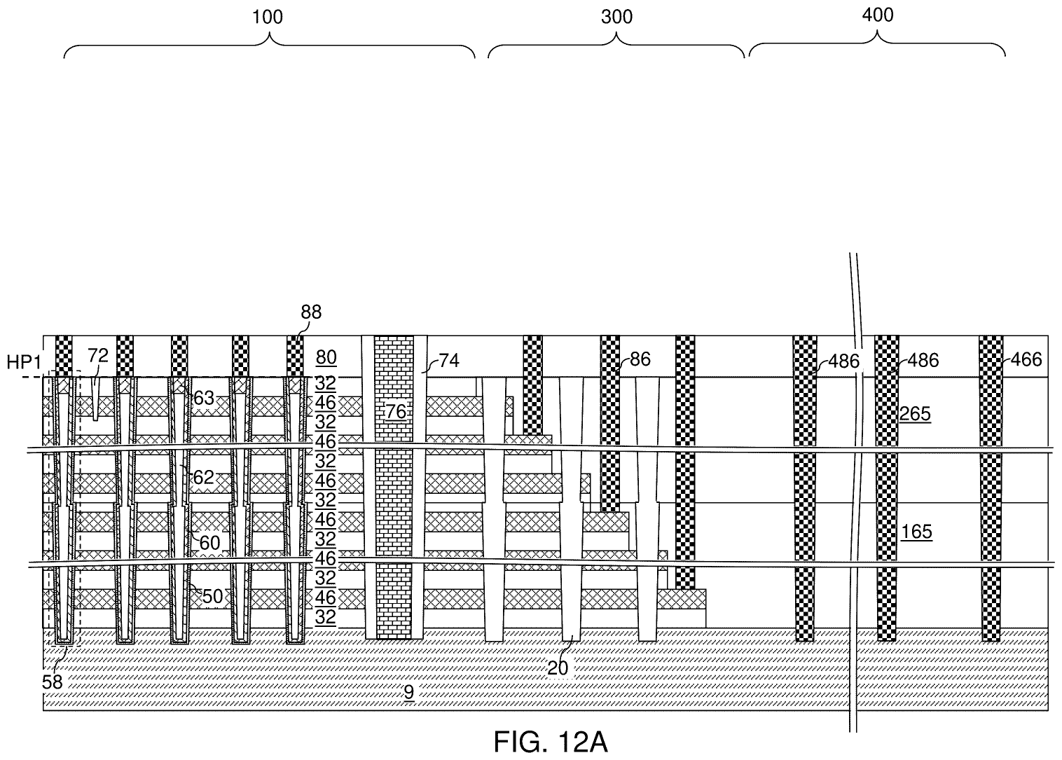

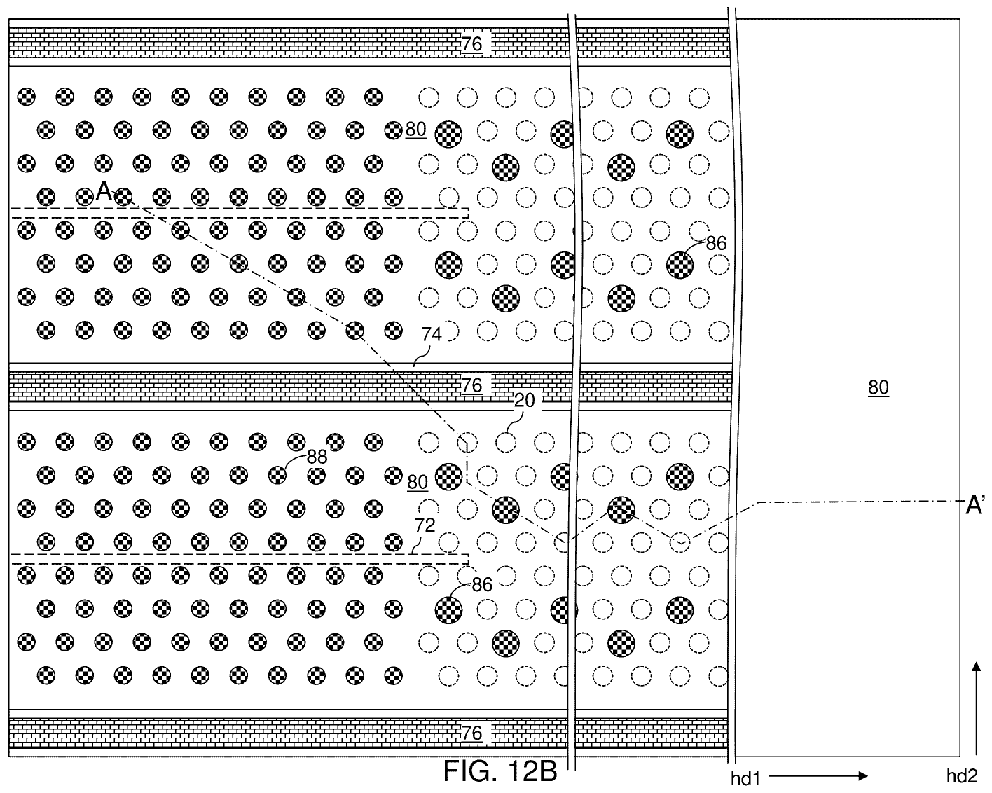

Referring to FIGS. 12A and 12B, at least one trench fill material may be deposited in the lateral isolation trenches 79 to form lateral isolation trench fill structures (74, 76). For example, an insulating material layer can be conformally deposited in peripheral regions of the lateral isolation trenches 79, and an anisotropic etch process can be performed to remove horizontally-extending portions of the insulating material layer. Each remaining vertically extending portion of the insulating material layer constitutes an insulating spacer 74. Each insulating spacer 74 may be elongated along the first horizontal direction hd2, and may be topologically homeomorphic to a torus. An electrically conductive material may be deposited in remaining unfilled volumes of the lateral isolation trenches 79, and excess portions of the electrically conductive material can be removed from above the horizontal plane including the top surface of the contact-level dielectric layer 80. Each remaining portion of the electrically conductive material filling a respective lateral isolation trench 79 constitutes a conductive wall structure 76. Each lateral isolation trench 79 may be filled with a respective combination of an insulating spacer 74 and a conductive wall structure 76, which is herein referred to as a lateral isolation trench fill structure (74, 76).

In an alternative embodiment, a dielectric fill material, such as silicon oxide, can be deposited in the lateral isolation trenches 79. Excess portions of the dielectric fill material can be removed from above the contact-level dielectric layer 80. Each remaining portion of the dielectric fill material that fills a respective one of the lateral isolation trenches 79 constitutes a lateral isolation trench fill structure, which may be a dielectric wall structure. Generally, each lateral isolation trench 79 can be filled with a respective lateral isolation trench fill structure.

Contact via structures (88, 86) can be formed through the contact-level dielectric layer 80, and optionally through the stepped dielectric material portions 65. For example, drain contact via structures 88 can be formed through the contact-level dielectric layer 80 on each drain region 63. Layer contact via structures 86 can be formed on the electrically conductive layers 46 through the contact-level dielectric layer 80, and through the stepped dielectric material portions 65. In addition, connection via structures 486 can be formed through the contact-level dielectric layer 80 and the stepped dielectric material portions 65 in the peripheral region 400. In one embodiment, the connection via structures 486 may extend into an upper portion of the substrate 9.

Further, an edge-seal via structure 466 can be formed along an outer periphery of the peripheral region 400 as a continuous ring-shaped structure. As used herein, a ring-shaped structure refers to a structure that is topologically homeomorphic to a ring, i.e., a structure that may be continuous deformed into the shape of a ring without creation of a new hole or destruction of any pre-existing hole. In one embodiment, the edge-seal via structure 466 may be formed as a component of a memory-die edge seal structure. The edge-seal via structure may laterally enclose all of the devices formed over the substrate 9.

In summary, a semiconductor structure can be provided. The semiconductor structure comprises: first alternating stacks (32, 46) of first insulating layers 32 and first electrically conductive layers 46. The first alternating stacks (32, 46) are laterally spaced apart from each other by first lateral isolation trenches 79 that laterally extend along a first horizontal direction (e.g., word line direction) hd1. The first lateral isolation trenches 79 may be filled with first lateral isolation trench fill structures (74, 76). The semiconductor structure further comprises: first memory openings 49 vertically extending through the first alternating stacks (32, 46); and first memory opening fill structures 58 located in the first memory openings 49. Each of the first memory opening fill structures 58 comprises a respective first vertical semiconductor channel 60, a respective vertical stack of first memory elements (e.g., memory cells comprising portions of a respective memory material layer 54), and a respective first drain region 63 contacting a first end of the respective first vertical semiconductor channel 60. The first electrically conductive layers 46 includes first word lines of the first memory elements of the first memory opening fill structures 58 as well as source side and drain side select gat electrodes.

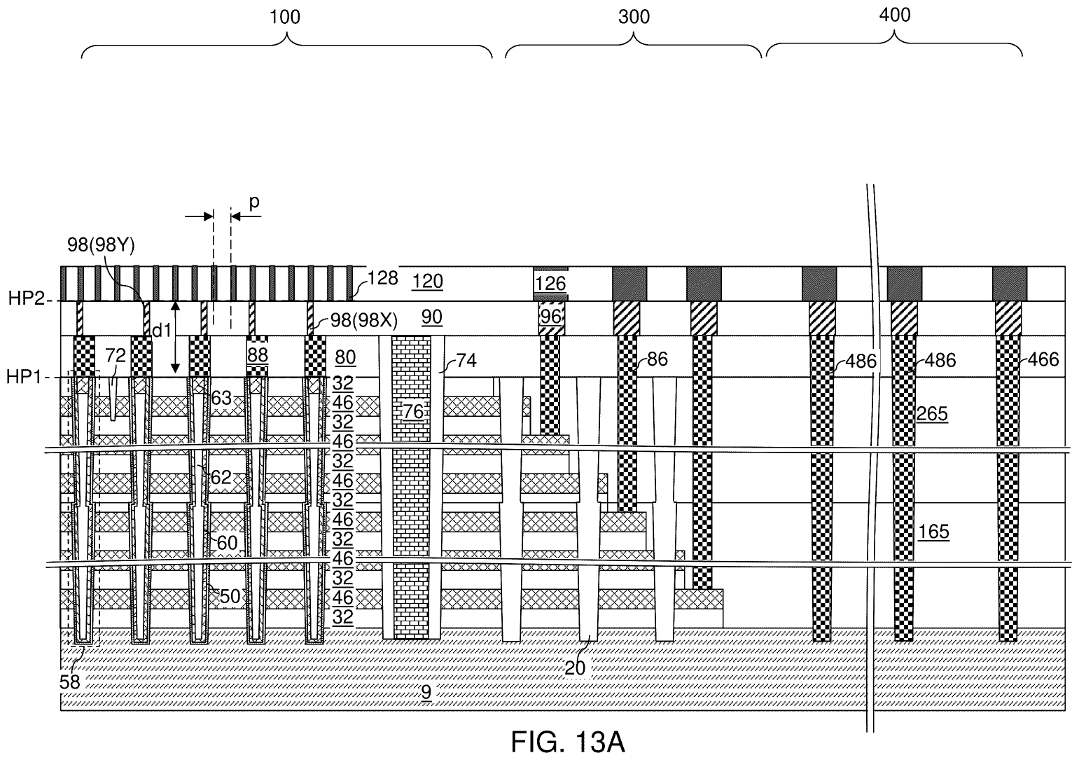

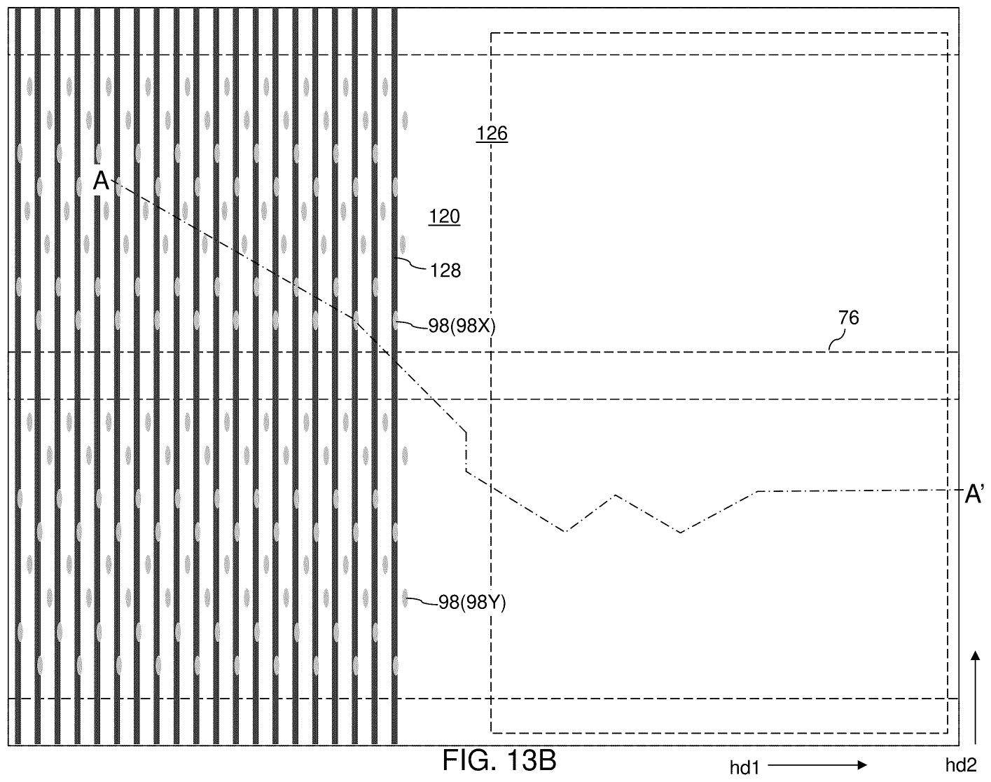

Referring to FIGS. 13A and 13B, a first via-level dielectric layer 90 can be formed over the contact-level dielectric layer 80. The first via-level dielectric layer 90 comprises a dielectric material, such as undoped silicate glass (e.g., silicon oxide), a doped silicate glass, or a porous or non-porous organosilicate glass. The first via-level dielectric layer 90 may be deposited by a chemical vapor deposition or by spin coating. The thickness of the first via-level dielectric layer 90 may be in a range from 50 nm to 300 nm, although lesser and greater thicknesses may also be employed.

First connection via structures 98 and additional connection via structures 96 can be formed in the first via-level dielectric layer 90. The first connection via structures 98 can be formed directly on the top surfaces of the drain contact via structures 88. Each drain contact via structure 88 can be contacted by a respective first connection via structure 98. The additional connection via structures 96 can be formed on a respective one of the layer contact via structures 86 and the connection via structures 486. An additional edge-seal via structure may be formed on a top surface of the edge-seal via structure 466.

A first bit-line-level dielectric layer 120 can be formed over the first via-level dielectric layer 90. The first bit-line-level dielectric layer 120 comprises a dielectric material, such as undoped silicate glass (e.g., silicon oxide), a doped silicate glass, or a porous or non-porous organosilicate glass. The first bit-line-level dielectric layer 120 may be deposited by a chemical vapor deposition or by spin coating. The thickness of the first bit-line-level dielectric layer 120 may be in a range from 50 nm to 300 nm, although lesser and greater thicknesses may also be employed.

First bit lines 128 and first-bit-line-level metal lines 126 can be formed in the first bit-line-level dielectric layer 120. Each of the first bit lines 128 may be formed on a respective first connection via structure 98 within a first subset of the first connection via structures 98. The first-bit-line-level metal lines 126 may be formed on a respective one of the additional connection via structures 96. An edge-seal line structure may be formed on a top surface of the additional edge-seal via structure.

According to an aspect of the present disclosure, the first subset 98X of the first connection via structures 98 are contacted by the first bit lines 128, and a second subset 98Y of the first connection via structures 98 are not contacted by the first bit lines 128. At least two vertical levels of bit lines can be formed in the first exemplary structure, and the first bit lines 128 comprise a lowermost subset of the bit lines of the first exemplary structure that is formed at the bottommost level. If a total of N levels of bit lines is to be formed in the first exemplary structure, the number of the first connection via structures 98 that is contacted by the first bit lines 128 may be 1/N times the total number of the first connection via structures 98 in the first exemplary structure. N is a positive integer greater than 1, and may be less than 6. In the illustrated example, N is 2 (i.e., there are two vertical levels bit lines).

The first exemplary structure illustrated in FIGS. 13A and 13B is located in a first semiconductor die, which can be a memory die. In the first exemplary structure, the first bit lines 128 can extend over each of the first alternating stacks (32, 46) along a second horizontal direction (e.g., bit line direction) hd2 that is perpendicular to the first horizontal direction (e.g., word line direction) hd1. The first bit lines 128 are electrically connected to a respective first subset of the first drain regions 63 via the respective via structures 88 and 98 (e.g., 98X), are vertically spaced by a first vertical distance d1 from a first horizontal plane HP1 including top surfaces of the first drain regions 63, and in one embodiment have a uniform pitch p along the first horizontal direction hd1. As used herein, a “pitch” refers to the shortest distance at which a periodic pattern is repeated. If a periodic pattern includes metal lines that are arranged with a periodicity along their lateral separation direction, the pitch of the metal lines may be a center-to-center distance between any neighboring pair of the metal lines along the direction of the periodicity.

In one embodiment, the entirety of the bottom surfaces of the first bit lines 128 may be formed within a second horizontal plane HP2. The vertical distance between the second horizontal plane HP2 and the first horizontal plane HP1 is the first vertical distance d1. In one embodiment, the entirety of the top surfaces of the first bit lines 128 may be formed within another horizontal plane. In one embodiment, the first connection via structures 98 can be located between the first horizontal plane HP1 and a second horizontal plane HP2 including bottom surfaces of the first bit lines 128. A first subset 98X of the first connection via structures 98 contacts a respective one of the first bit lines 128.

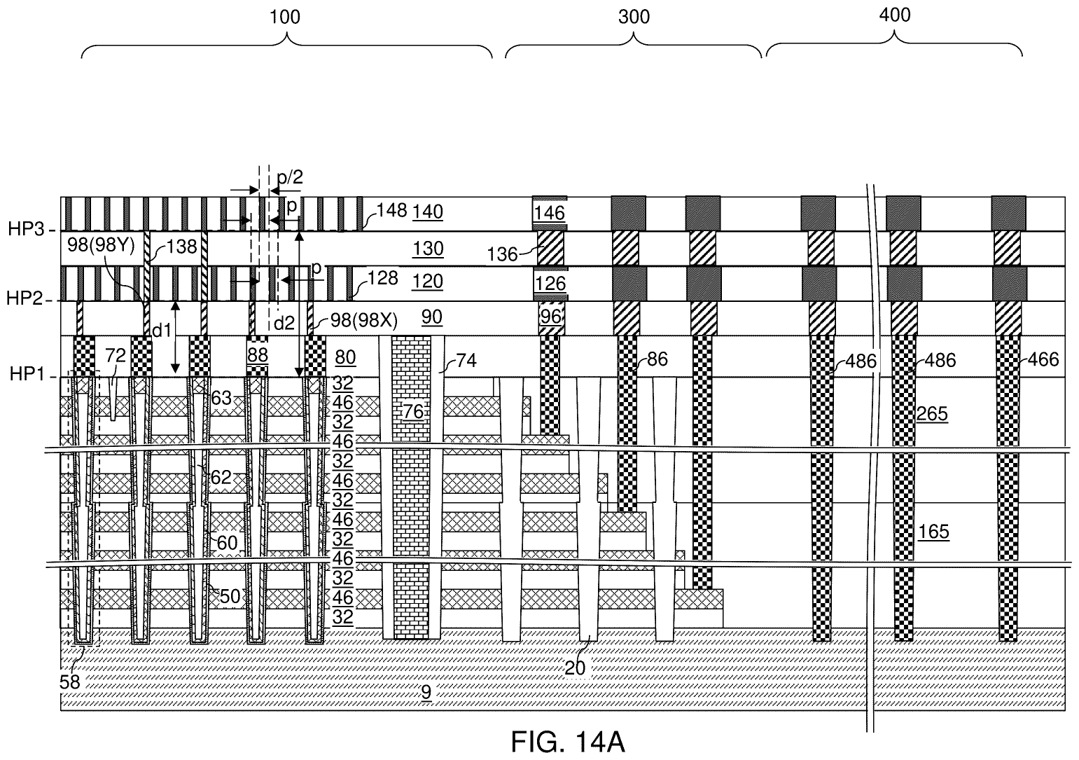

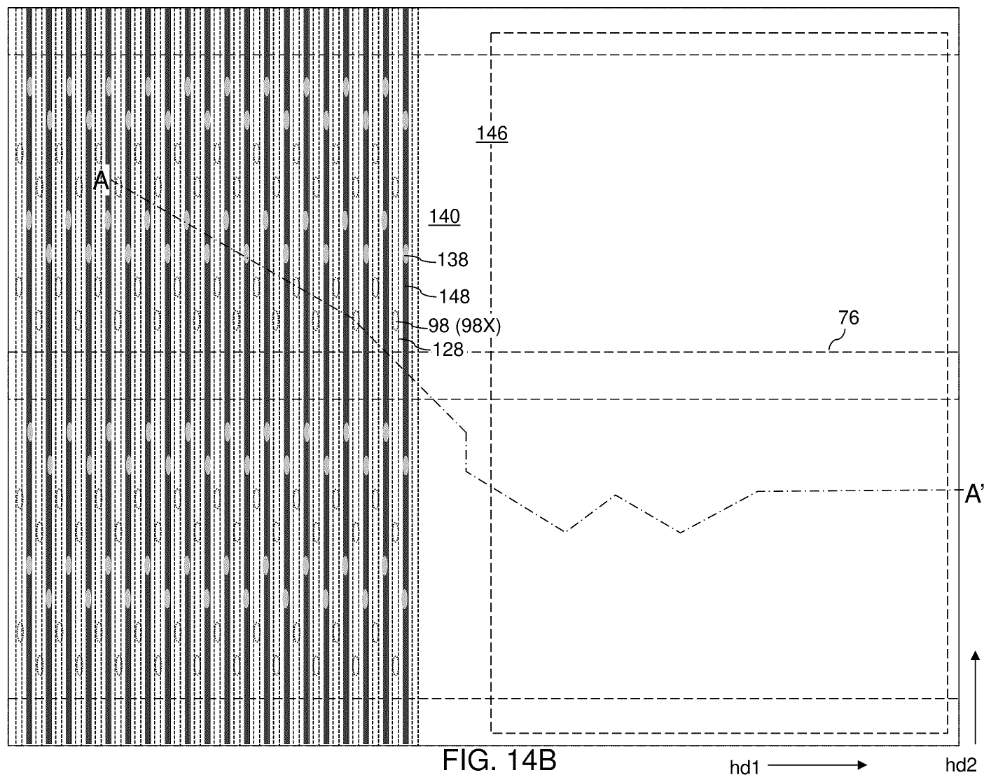

Referring to FIGS. 14A and 14B, a second via-level dielectric layer 130 can be formed over the first bit-line-level dielectric layer 120. The second via-level dielectric layer 130 comprises a dielectric material, such as undoped silicate glass (e.g., silicon oxide), a doped silicate glass, or a porous or non-porous organosilicate glass. The second via-level dielectric layer 130 may be deposited by a chemical vapor deposition or by spin coating. The thickness of the second via-level dielectric layer 130 may be in a range from 50 nm to 300 nm, although lesser and greater thicknesses may also be employed.

Second connection via structures 138 can be formed through the second via-level dielectric layer 130 and the first bit-line-level dielectric layer 120 to contact the second subset 98Y of the first connection via structures 98 that do not contact the first bit lines 128. Each of the second connection via structures 138 vertically extends through a lateral gap between a respective neighboring pair of first bit lines 128. The second connection via structures 138 can be formed directly on the top surfaces of second subset 98Y of the first connection via structures 98. Each first connection via structure 98 within the second subset 98Y of the first connection via structures 98 can be contacted by a respective second connection via structure 138. Additional connection via structures 136 can be formed in the second via-level dielectric layer 130. The additional connection via structures 136 can be formed on a respective one of the bit-line-level metal lines 126. An additional edge-seal via structure may be formed in the second via-level dielectric layer 130.

A second bit-line-level dielectric layer 140 can be formed over the second via-level dielectric layer 130. The second bit-line-level dielectric layer 140 comprises a dielectric material, such as undoped silicate glass (e.g., silicon oxide), a doped silicate glass, or a porous or non-porous organosilicate glass. The second bit-line-level dielectric layer 140 may be deposited by a chemical vapor deposition or by spin coating. The thickness of the second bit-line-level dielectric layer 140 may be in a range from 50 nm to 300 nm, although lesser and greater thicknesses may also be employed.

Second bit lines 148 and second-bit-line-level metal lines 146 can be formed in the second bit-line-level dielectric layer 140. Each of the second bit lines 148 may be formed on a respective one of the second connection via structures 138. The second-bit-line-level metal lines 146 may be formed on a respective one of the additional connection via structures 136. An edge-seal line structure may be formed on a top surface of an underlying edge-seal via structure.

Generally, the second bit lines 148 extend over the first bit lines 128 along the second horizontal direction hd2, and thus, are parallel to the first bit lines 128. Each of the second bit lines 148 is electrically connected to a respective second subset of the first drain regions 63 through the respective via structures 88 and 98 (e.g., 98Y), and is vertically spaced by a second vertical distance d2 that is greater than the first vertical distance d1 from the first horizontal plane HP1. The second bit lines 148 may have the uniform pitch p along the first horizontal direction hd1.

In one embodiment, the first exemplary structure comprises first connection via structures 98 located between the first horizontal plane HP1 and a second horizontal plane HP2 including bottom surfaces of the first bit lines 128. A first subset 98X of the first connection via structures 98 contacts a respective one of the first bit lines 128. The first exemplary structure further comprises second connection via structures 138 vertically extending between the second horizontal plane HP2 and a third horizontal plane HP3 including bottom surfaces of the second bit lines 148 and located between a respective neighboring pair of first bit lines 128. The second connection via structures 138 contact top surfaces of a second subset 98Y of the first connection via structures 98. A subset of the second connection via structures 138 contacts bottom surfaces of the second bit lines 148.

As discussed above, multiple levels of bit lines can be formed in the first exemplary structure, and the second bit lines 148 comprise a subset of the bit lines of the first exemplary structure that is formed at a vertical level that overlies the level of the first bit lines 128. If a total of N levels of bit lines is to be formed in the first exemplary structure, the number of the second connection via structures 138 that is contacted by the second bit lines 148 may be 1/N times the total number of the first connection via structures 98 in the first exemplary structure. The total number of the second connection via structures 138 may be t (N−1)/N times the total number of the first connection via structures 98 in the first exemplary structure. N is a positive integer greater than 1, and may be less than 6. In the illustrated example, N is 2, and the second bit lines 148 comprise the topmost bit lines.

According to an aspect of the present disclosure, the second bit lines 148 may be laterally offset along the first horizontal direction hd1 by a lateral offset distance of p/N relative to the first bit lines 128, in which N is a positive integer less than 7, such as 2 to 6. In one embodiment, bottom surfaces of the second bit lines 148 are located above a horizontal plane including top surfaces of the first bit lines 128. Generally, the second connection via structures 138 contact top surfaces of a second subset of the first connection via structures 98, and a first subset of the second connection via structures 138 contacts bottom surfaces of the second bit lines 148.

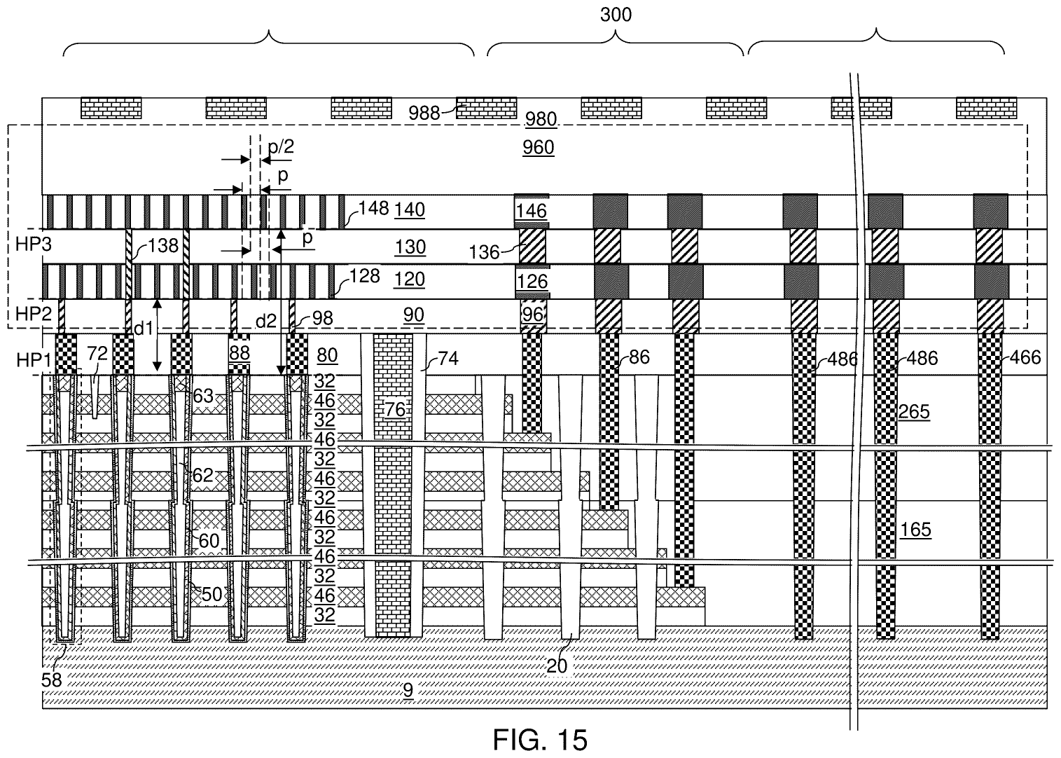

Referring to FIG. 15, additional dielectric material layers and additional metal interconnect structures can be formed. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. For example, if the total numbers of levels of bit lines is greater than 2, the additional dielectric material layers may comprise at least one additional via-level dielectric layer and at least one additional bit-line-level dielectric layer, and the additional metal interconnect structures may comprise additional connection via structures and additional bit lines. If a total of N levels of bit lines is formed in the first exemplary structure, for each integer i that is not greater than N, the total number of i-th connection via structures may be (N−i+1)/N times the total number of the first connection via structures 98 in the first exemplary structure. Each i-th connection via structure may contact a top surface of a respective (i−1)-th connection via structure. The number of the i-th connection via structures that contacts an overlying i-th bit line may be 1/N times the total number of the first connection via structures 98. The total number of the first connection via structures 98 may be the same as the total number of the drain contact via structures 88 and drain regions 63, and may be the same as the total number of the first memory opening fill structures 58 in the first exemplary structure.

The first via-level dielectric layer 90, the first bit-line-level dielectric layer 120, the second via-level dielectric layer 130, the second bit-line-level dielectric layer 140, and the additional dielectric material layers that are formed above the contact-level dielectric layer 80 are herein referred to as memory-die dielectric material layers 960. The first connection via structures 98, additional connection via structures (96, 136), the first bit lines 128, the first bit-line-level metal lines 126, second connection via structures 138, the second bit lines 148, the second bit-line-level metal lines 146, and any additional metal interconnect structures are collectively referred to as memory-die metal interconnect structures 980.

Metal bonding pads, which are herein referred to memory-die bonding pads 988, may be formed at the topmost level of the memory-die dielectric material layers 960 to complete a memory die 900. A subset of the memory-die bonding pads 988 may be electrically connected to the memory-die metal interconnect structures 980 and various nodes of the three-dimensional memory array including the electrically conductive layers 46 and the drain regions 63 of the memory opening fill structures 58.

In summary, the memory-die dielectric material layers 960 are formed over the alternating stacks (32, 46). The memory-die metal interconnect structures 980 are embedded in the memory-die dielectric material layers 960. The memory-die bonding pads 988 can be embedded within the memory-die dielectric material layers 960, and specifically, within the topmost layer among the memory-die dielectric material layers 960. The memory-die bonding pads 988 can be electrically connected to the memory-die metal interconnect structures 980.

The first exemplary structure may comprise a plurality of memory dies. In this case, in the first embodiment, the first bit lines 128, the second bit lines 148, and the first alternating stacks (32, 46) can be formed within a single memory die.

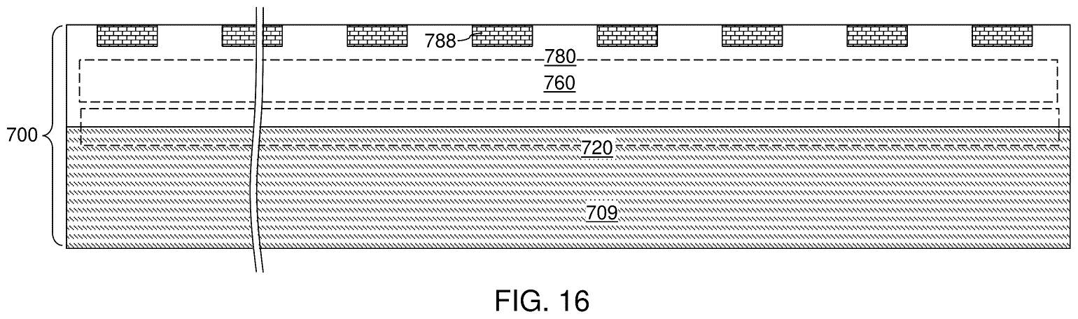

Referring to FIG. 16, a logic die 700 can be provided. The logic die 700 includes a logic-die substrate 709, a driver circuit 720 located on the logic-die substrate 709 and comprising logic-die semiconductor devices (such as field effect transistors), logic-die metal interconnect structures 780 embedded within logic-die dielectric material layers 760, and logic-die bonding pads 788. The driver circuit 720 can be configured to control operation of the memory array within the memory die 900. Specifically, the driver circuit 720 can be configured to drive various electrical components within the memory array including, but not limited to, the electrically conductive layers 46, the drain regions 63 (via the bit lines 128), and a source layer. The driver circuit 720 can be configured to control operation of the vertical stack of memory elements (e.g., memory cells) in the memory array in the memory die 900.

In one embodiment, the driver circuit 720 includes a source line driver, word line drivers, and bit line drivers. Generally, the driver circuit 720 can be configured to electrically bias the word lines and each of the bit lines including the first bit lines 128 and the second bit lines 148. The logic-die dielectric material layers 760 embed logic-die metal interconnect structures 780 and logic-die bonding pads 788. The pattern of the logic-die bonding pads 788 may be a mirror image pattern of the pattern of the memory-die bonding pads 988.

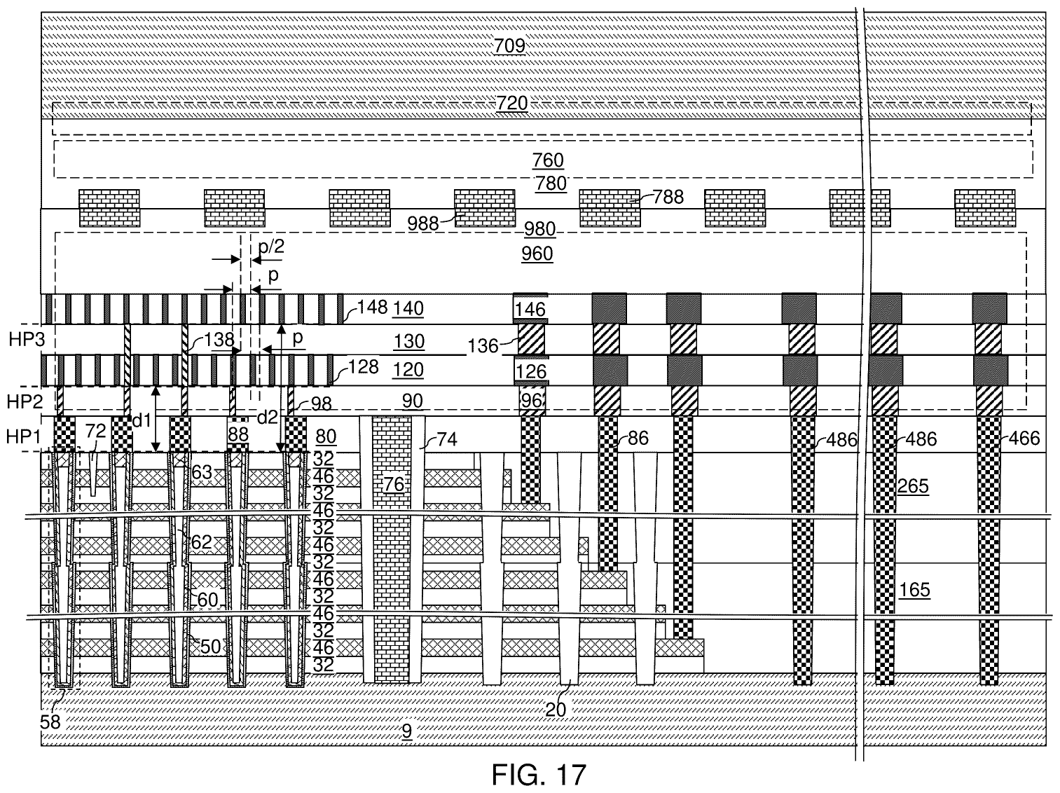

Referring to FIG. 17, the logic die 700 can be attached to the memory die illustrated in FIG. 15, for example, by bonding the logic-die bonding pads 788 to the memory-die bonding pads 988 at a bonding interface. Plasma treatment processes and chemical cleaning processes can be performed to clean the surfaces of the memory-die bonding pads 988 and the logic-die bonding pads 788 prior to bonding the logic-die bonding pads 788 to the memory-die bonding pads 988.

The bonding between the memory die and the logic die 700 may be performed employing a wafer-to-wafer bonding process in which a two-dimensional array of memory dies is bonded to a two-dimensional array of logic dies 700, by a die-to-bonding process, or by a die-to-die bonding process. The logic-die bonding pads 788 within each logic die 700 can be bonded to the memory-die bonding pads 988 within a respective memory die. A bonded assembly of the memory die and the logic die 700 is provided. The logic-die bonding pads 788 can be bonded to the memory-die bonding pads 988 via metal-to-metal bonding, such as copper-to-copper bonding.

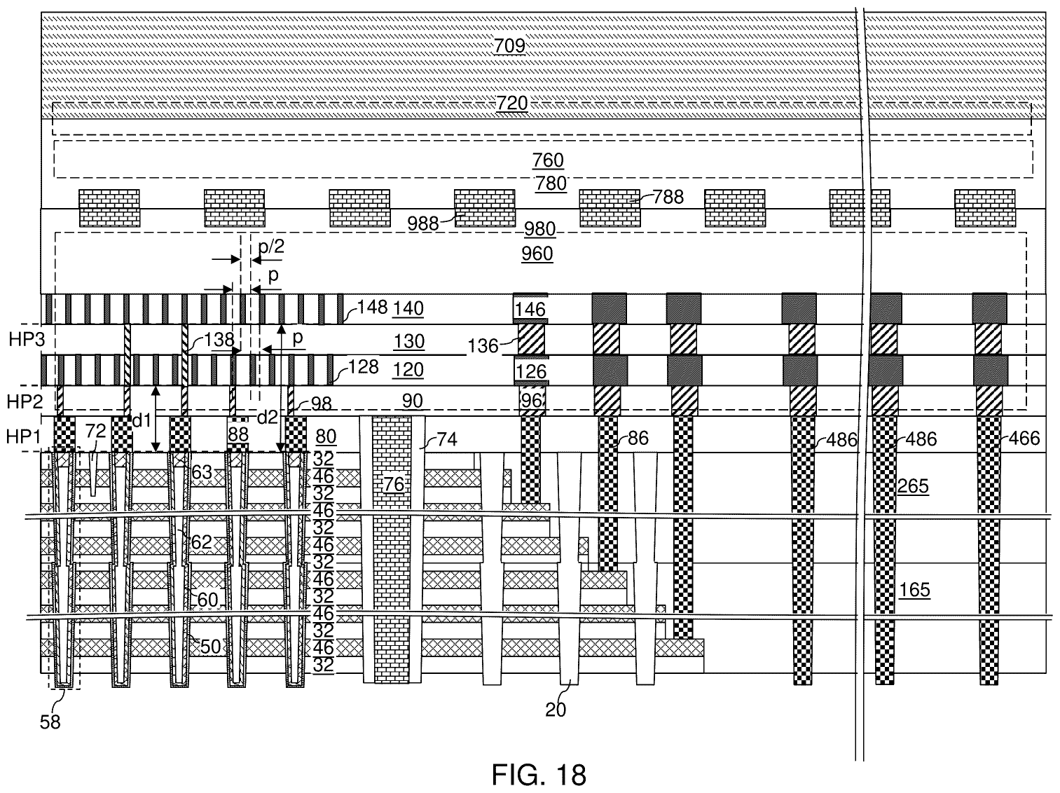

Referring to FIG. 18, the substrate 9 can be removed, for example, by grinding, polishing, cleaving, an isotropic etch process, an anisotropic etch process, and/or a combination thereof.

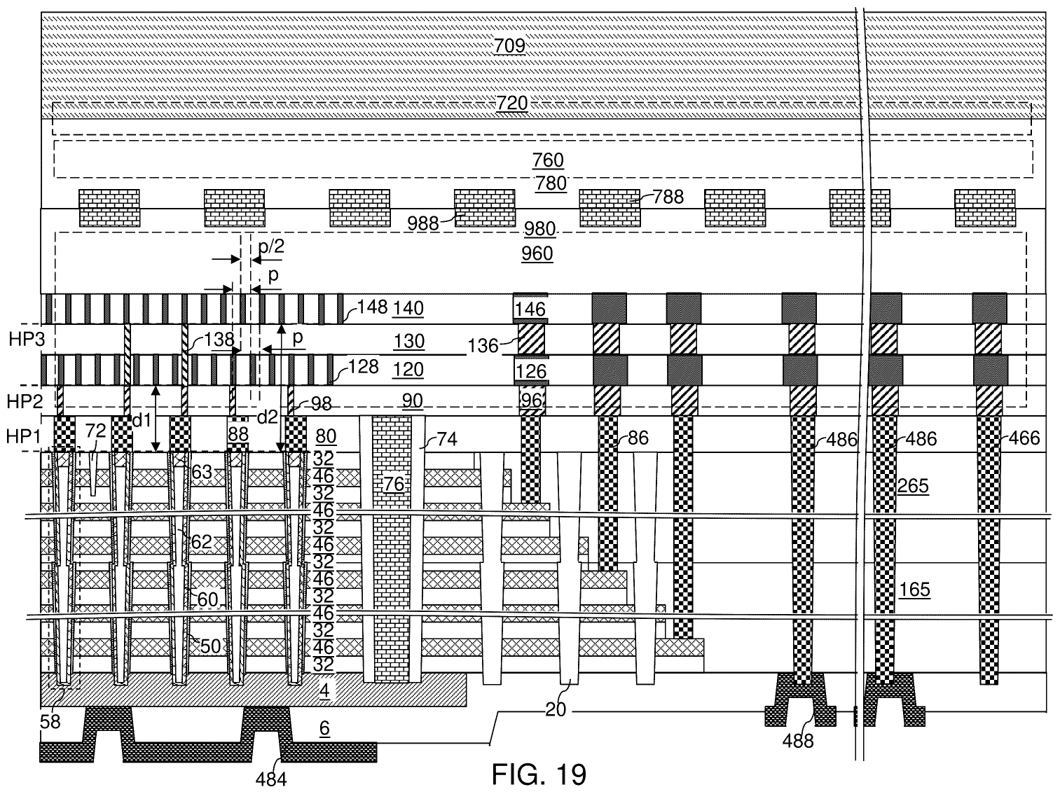

Referring to FIG. 19, physically exposed bottom end portions of the memory films 50 can be removed by performing at least one selective etch process such as at least one wet etch process without etching the material of the vertical semiconductor channels 60. A source layer 4 can be formed the physically exposed second end portions of the vertical semiconductor channels 60. The source layer 4 underlies the first alternating stacks (32, 46) and contacts second ends of the vertical semiconductor channels 60. An optional backside insulating layer 6 can be formed on the backside surface of the source layer 4. Backside source contact structures 484 can be formed on the source layer 4. Backside contact pad structures 488 can be formed on an end surface of a respective one of the connection via structures 486.

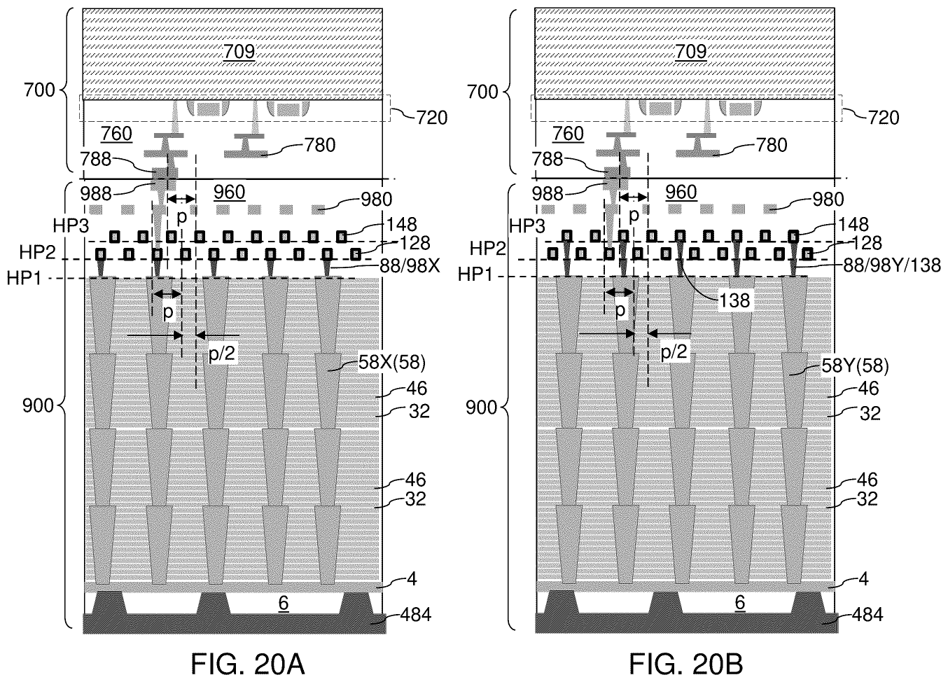

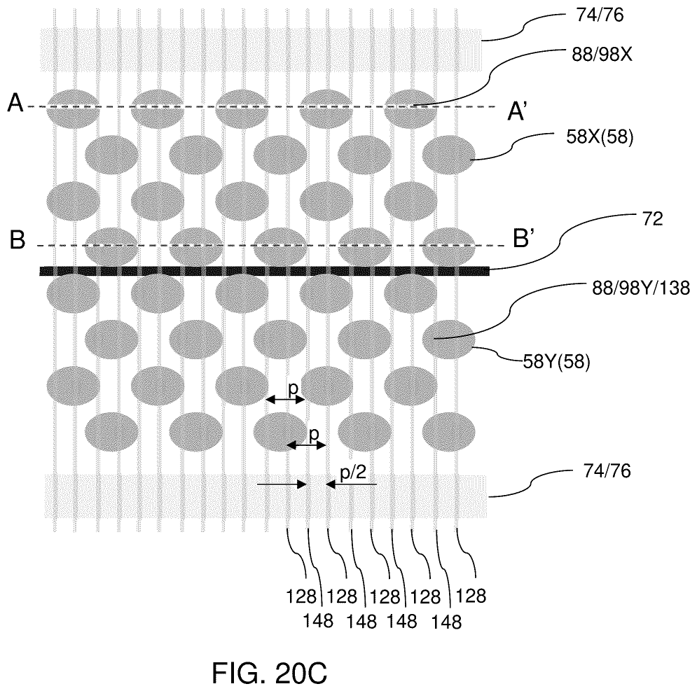

Referring to FIGS. 20A-20C, various views of a first alternative embodiment of the first exemplary structure are illustrated. FIG. 20A is a vertical cross-sectional view along a first vertical plane that cuts through a first subset 98X of the first connection via structures 98. FIG. 20B is a second vertical cross-sectional view of the first alternative embodiment of the first exemplary structure along a second vertical plane that cuts through a second subset 98Y of the first connection via structures 98. FIG. 20C is a plan view of the first alternative embodiment of the first exemplary structure illustrated in FIGS. 20A and 20B. The vertical plane A-A′ is the cut plane of the vertical cross-sectional view of FIG. 20A. The vertical plane B-B′ is the cut plate of the vertical cross-sectional view of FIG. 20B.

The first alternative embodiment of the first exemplary structure can be derived from the first exemplary structure by forming four alternating stacks of insulating layers 32 and sacrificial material layers 42 prior to formation of memory opening fill structures 58 and the lateral isolation trenches 79. The total number N of the levels of the bit lines (128, 148) is 2 for the first alternative embodiment of the first exemplary structure. An assembly is formed over a substrate 9 such that the assembly includes first alternating stacks (32, 46) of first insulating layers 32 and first electrically conductive layers 46 and first memory opening fill structures 58 vertically extending through the first alternating stacks (32, 46). The first alternating stacks (32, 46) are laterally spaced apart from each other by first lateral isolation trenches 79 that laterally extend along a first horizontal direction hd1 and are filled by respective lateral isolation trench fill structures (74, 76). Each of the first memory opening fill structures 58 comprises a respective first vertical semiconductor channel 60, a respective vertical stack of first memory elements (i.e., memory cells, such as portions of a respective memory material layer 54), and a respective first drain region 63 contacting a first end of the respective first vertical semiconductor channel 60. The first electrically conductive layers 46 comprise first word lines of the first memory elements (e.g., portions of a respective memory material layer 54) of the first memory opening fill structures 58. The first memory opening fill structures 58 comprise a first subset of memory opening fill structures 58X including respective drain regions 63 in electrical contact with the first bit lines 128 through the respective via structures (88, 98X), and a second subset of memory opening fill structures 58Y including respective drain regions 63 in electrical contact with the second bit lines 128 through the respective via structures (88, 98Y, 138). The alternating stacks (32, 46), the memory opening fill structures 58, the first bit lines 128, and the second bit lines 148 are formed in a first memory die 900. Subsequently, the processing steps described with reference to FIGS. 15-19 may be performed.

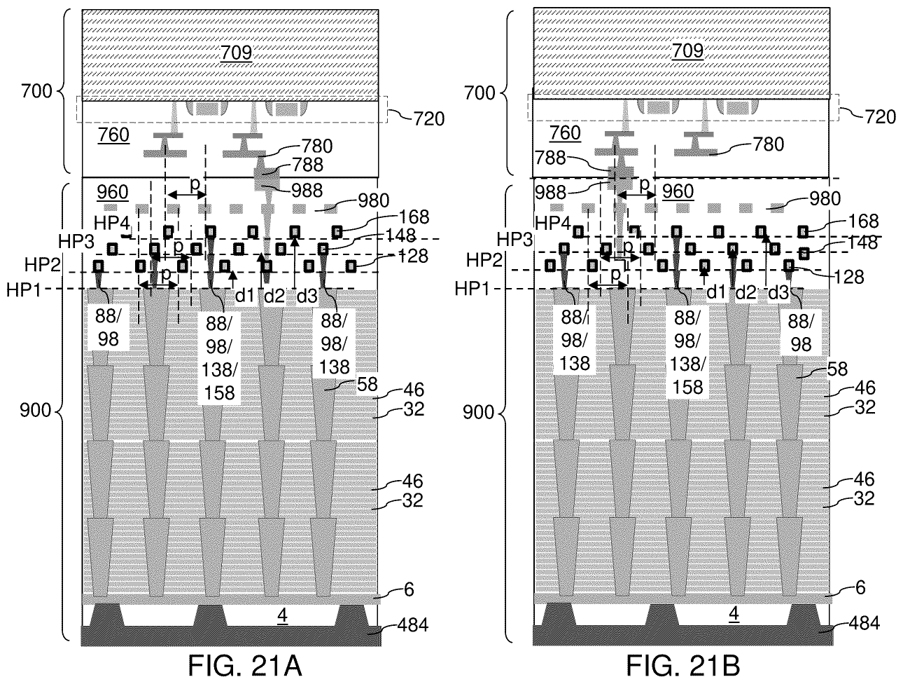

Referring to FIGS. 21A and 21B, a second alternative embodiment of the first exemplary structure is illustrated. FIG. 21A is a first vertical cross-sectional view of a second alternative embodiment of the first exemplary structure along a first vertical plane that cuts through a subset of the first connection via structures. FIG. 21B is a second vertical cross-sectional view of the second alternative embodiment of the first exemplary structure along a second vertical plane that cuts through another subset of the first connection via structures 98. The total number N of the levels of the bit lines (128, 148, 168) is 3 for the second alternative embodiment of the first exemplary structure. In the second alternative embodiment of the present disclosure, third bit lines 168 can be formed over the second bit lines 148. The third bit lines 168 extend over the second bit lines 148 along the second horizontal direction hd2, are electrically connected to a respective third subset of the first drain regions 63 through respective via connection structures (88, 98, 138, 158), are vertically spaced by a third vertical distance d3 that is greater than the second vertical distance d2 from the first horizontal plane HP1, and have the uniform pitch p along the first horizontal direction hd1.

The bottom surfaces of the third bit lines 168 may be formed entirely within a fourth horizontal plane HP4 that overlies the horizontal plane including the entirety of the top surfaces of the second bit lines 148. The top surfaces of the third bit lines 168 may be formed entirely within another horizontal plane. The second bit lines 148 may be laterally offset from the first bit lines 128 along the first horizontal direction hd1 by 1/3 times the uniform pitch p, and the third bit lines 168 may be laterally offset from the first bit lines 128 along the first horizontal direction hd1 by 2/3 times the uniform pitch p. Generally speaking, if N levels of the bit lines (128, 148, 168) are formed, each set of bit lines located at any level may be laterally offset relative to any other set of bit lines located at a different level by j/N times the uniform pitch, in which j is a positive integer less than N. Further, each set of bit lines can be formed such that there is no areal overlap among different sets of bit lines in a plan view such as a see-through top-down view.

In a second embodiment, the vertically separated bit lines are located in different bonded memory die. Each of the bit lines is electrically connected to drain regions 63 of the memory opening fill structures 58 in both memory dies through respective bonding pads.

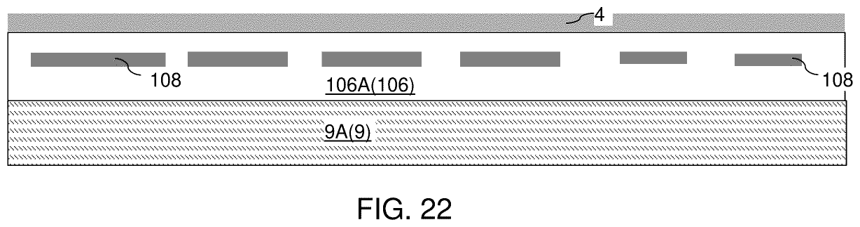

FIG. 22 illustrates a second exemplary structure according to the second embodiment of the present disclosure, which comprises a first substrate 9A (which is a substrate 9), a first backside insulating layer 106A (which is one of the backside insulating layers 106) embedding backside metal interconnect structures 108, and a first source layer 4A (which is one of the source layers 4). The first source layer 4A may comprise a heavily doped semiconductor layer, and may optionally comprise an underlying metallic material layer.

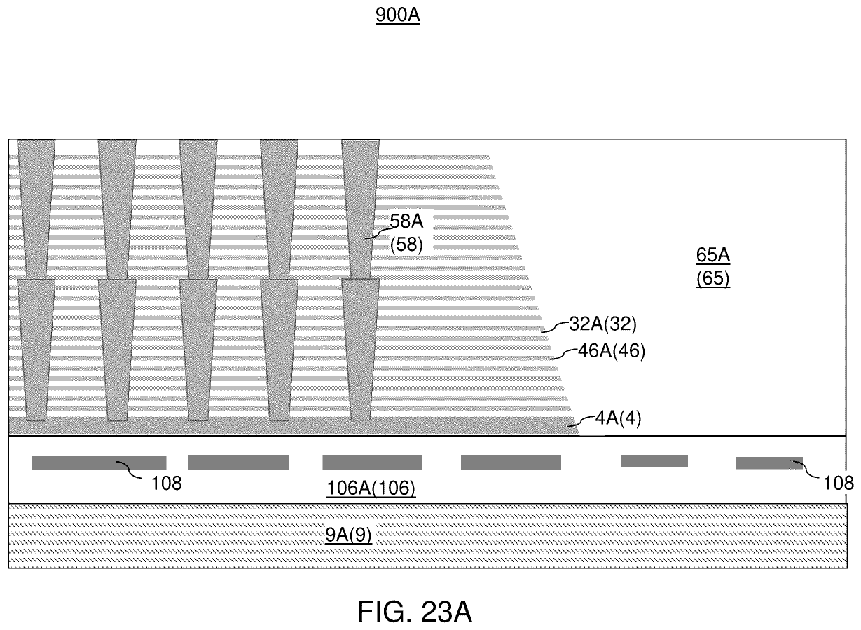

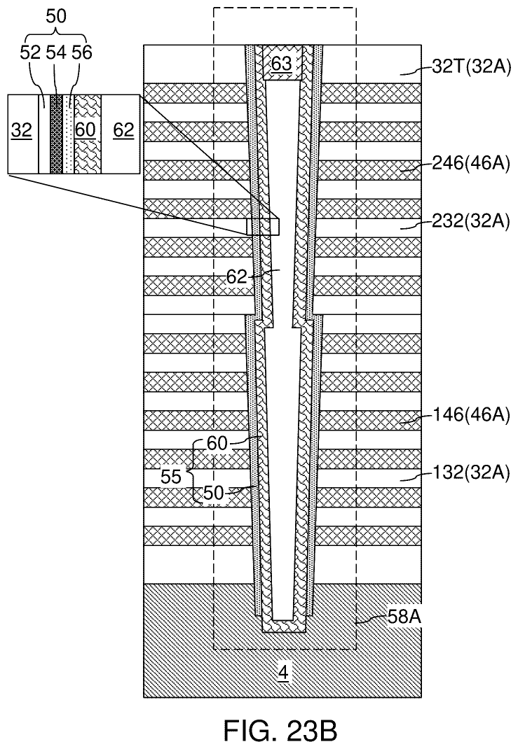

Referring to FIGS. 23A and 23B, the processing steps described with reference to FIGS. 1-11 can be performed to form an assembly of alternating stacks (32, 46) of insulating layers 32 and electrically conductive layers 46, memory opening fill structures 58, and a stepped dielectric material portion 65 in a first memory die 900A. As such, the alternating stacks (32, 46) of insulating layers 32 and electrically conductive layers 46 are herein referred to as first alternating stacks (32A, 46A) of first insulating layers 32A and first electrically conductive layers 46A, the memory opening fill structures 58 are herein referred to as first memory opening fill structures 58A, and the stepped dielectric material portion 65 is herein referred to as a first stepped dielectric material portion 65A. The lateral isolation trenches (shown in FIGS. 9A and 9B and not illustrated in FIGS. 23A and 23B for clarity) are herein referred to as first lateral isolation trenches, and the lateral isolation trench fill structures are herein referred to as first lateral isolation trench fill structures.

In summary, a semiconductor structure is formed in a first memory die 900A. The semiconductor structure comprises: first alternating stacks (32A, 46A) of first insulating layers 32A and first electrically conductive layers 46A; first memory openings 49 vertically extending through the first alternating stacks (32A, 46A); and first memory opening fill structures 58A located in the first memory openings 49. The first alternating stacks (32A, 46A) are laterally spaced apart from each other by first lateral isolation trenches 79 that laterally extend along a first horizontal direction hd1. Each of the first memory opening fill structures 58A comprises a respective first vertical semiconductor channel 60, a respective vertical stack of first memory elements (i.e., memory cells, such as portions of a respective memory material layer 54), and a respective first drain region 63 contacting a first end of the respective first vertical semiconductor channel 60. The first electrically conductive layers 46A comprise first word lines of the first memory elements of the first memory opening fill structures 58A. A first source layer 4A underlies the first alternating stacks (32A, 46A) and contacts second ends of the vertical semiconductor channels 60.

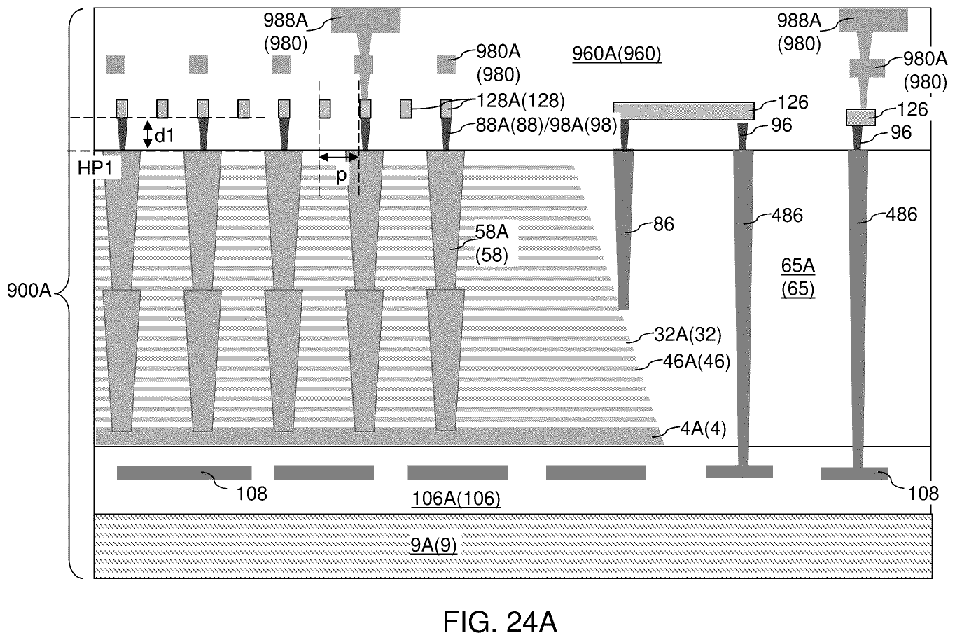

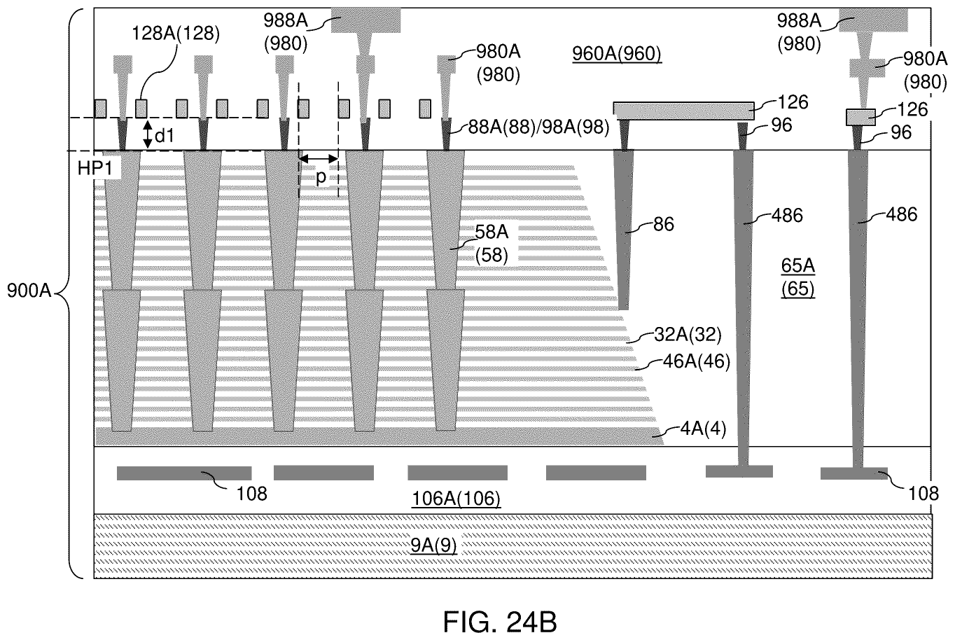

Referring to FIGS. 24A and 24B, the processing steps described with reference to FIGS. 12A and 12B, 13A and 13B, and 15 can be performed without performing the processing steps described with reference to FIGS. 14A and 14B to provide a first memory die 900A. Thus, a second via-level dielectric layer 130, second connection via structures 138, a second bit-line-level dielectric layer 140, and second bit lines 148 are not formed in the second exemplary structure. The drain contact via structures 88 in the first memory die 900A are herein referred to as first drain contact via structures 88A. The connection via structures 98 in the first memory die 900A are herein referred to as first connection via structures 98A. The first bit lines 128 in the first memory die 900A are herein referred to as first bit lines 128A. The memory-die dielectric material layers 960 in the first memory die 900A are herein referred to as first memory-die dielectric material layers 960A. The memory-die metal interconnect structures 980 in the first memory die 900A are herein referred to as first memory-die metal interconnect structures 980A.

The first bit lines 128A extend over each of the first alternating stacks (32A, 46A) along a second horizontal direction (i.e., bit line direction) hd2 (as shown in FIG. 13B) that is perpendicular to the first horizontal direction hd1. Each of the first bit lines 128A is electrically connected to a respective first subset of the first drain regions 63 through respective via structures (88A, 98A). The first bit lines 128A are vertically spaced by a first vertical distance d1 from a first horizontal plane HP1 including top surfaces of the first drain regions 63, and have a uniform pitch p along the first horizontal direction hd1. Each of the first drain contact via structures 88A is contacted by a respective first connection via structure 98A. A first subset of the first connection via structures 98A contacts a bottom surface of a respective one of the first bit lines 128A, as shown in FIG. 24A. A second subset of the first connection via structures 98A is contacted by a respective metal via structure which is one of the first memory-die metal interconnect structures 980A and vertically extends between a respective neighboring pair of first bit lines 128A of the first bit lines 128A, as shown in FIG. 24B.

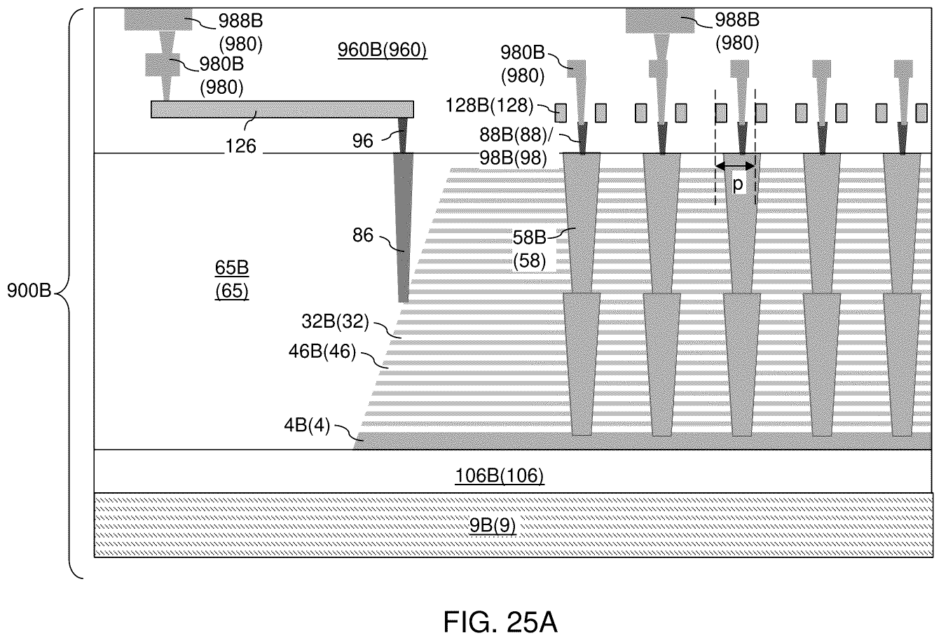

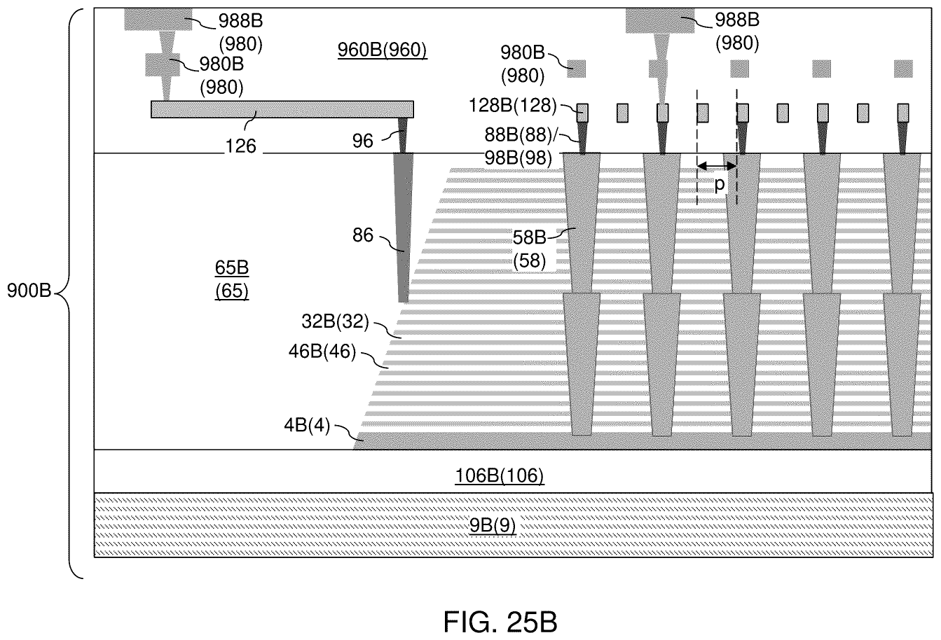

Referring to FIGS. 25A and 25B, an additional semiconductor memory die 900B is provided. The additional semiconductor die comprises second bit lines 128B having a pitch that equals the uniform pitch p. The second memory die 900B may be formed by performing the processing steps described with reference to FIGS. 22-24. Optionally, formation of the backside metal interconnect structures 108 may be omitted during formation of the second memory die 900B.

The second memory die 900B may comprises: second alternating stacks (32B, 46B) of second insulating layers 32B and second electrically conductive layers 46B; second memory openings 49 vertically extending through the second alternating stacks (32B, 46B); and second memory opening fill structures 58B located in the second memory openings 49. The second alternating stacks (32B, 46B) are laterally spaced apart from each other by second lateral isolation trenches 79 that laterally extend along the first horizontal direction hd1. Each of the second memory opening fill structures 58B comprises a respective second vertical semiconductor channel 60, a respective vertical stack of second memory elements (e.g., portions of a respective memory material layer 54), and a respective second drain region 63 contacting a second end of the respective second vertical semiconductor channel 60. The second electrically conductive layers 46B comprise second word lines of the second memory elements of the second memory opening fill structures 58B. A second source layer 4B underlies the second alternating stacks (32B, 46B) and contacts second ends of the vertical semiconductor channels 60.

The drain contact via structures 88 in the second memory die 900B are herein referred to as second drain contact via structures 88B. The connection via structures 98 in the second memory die 900B are herein referred to as second connection via structures 98B. The second bit lines 128 in the second memory die 900B are herein referred to as second bit lines 128B. The memory-die dielectric material layers 960 in the second memory die 900B are herein referred to as second memory-die dielectric material layers 960B. The memory-die metal interconnect structures 980 in the second memory die 900B are herein referred to as second memory-die metal interconnect structures 980B.

The second bit lines 128B extend over each of the second alternating stacks (32B, 46B) along a horizontal direction that is perpendicular to the lengthwise direction of the second lateral isolation trench fill structures. Each of the second bit lines 128B is electrically connected to a respective first subset of the second drain regions 63. A first subset of the second connection via structures 98B contacts a bottom surface of a respective one of the second bit lines 128B, as shown in FIG. 25B. A second subset of the second connection via structures 98B is contacted by a respective metal via structure which is one of the second memory-die metal interconnect structures 980B and vertically extends between a respective neighboring pair of second bit lines 128B of the second bit lines 128B, as shown in FIG. 25A.

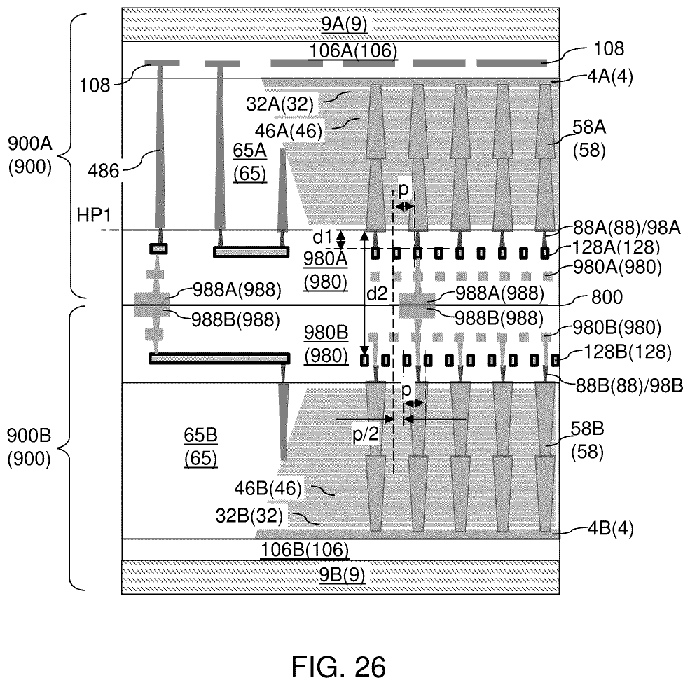

Referring to FIG. 26, the second memory die 900B can be bonded to the first memory die 900A, for example, by metal-to-metal bonding. For example, the second memory-die bonding pads 988B may be bonded to the first memory-die bonding pads 988A by metal-to-metal bonding. A bonding interface 800 is located between the first and second memory dies (900A, 900B). Generally, an additional semiconductor die (such as the second memory die 900B) may be bonded to the first memory die 900A such that the second bit lines 128B extend over the first bit lines 128A along the second horizontal direction hd2, are electrically connected to a respective second subset of the first drain regions 63, are vertically spaced by a second vertical distance d2 that is greater than the first vertical distance d1 from the first horizontal plane HP1, and have the uniform pitch p along the first horizontal direction hd1.

The first bit lines 128A and the first alternating stacks (32A, 46A) are located within a first memory die 900A, which comprises first bonding pads (such as first memory-die bonding pads 988A) embedded in first dielectric material layers 960A. The second bit lines 128B are located within a second memory die 900B that is bonded to the first memory die 900A. The second memory die 900B comprises second bonding pads (such as second memory-die bonding pads 988B) embedded in second dielectric material layers 960B and bonded to the first bonding pads (such as first memory-die bonding pads 988A).

In one embodiment, each of the first bit lines 128A is electrically connected to a respective first subset of the second drain regions 63 located in both the first and the second memory dies (900A, 900B) upon bonding the second memory die 900B to the first memory die 900A, and each of the second bit lines 128B is electrically connected to a respective second subset of the second drain regions 63 located in both the first and the second memory dies (900A, 900B).

The second bit lines 128B extend over the first bit lines 128A along the second horizontal direction hd2, are electrically connected to a respective second subset of the first drain regions 63, are vertically spaced by a second vertical distance d2 that is greater than the first vertical distance d1 from the first horizontal plane HP1, and have the uniform pitch p along the first horizontal direction hd1. The second bit lines 128B are laterally offset along the first horizontal direction hd1 by a lateral offset distance relative to the first bit lines 128A. In one embodiment, the bottom surfaces of the second bit lines 128B are located above a horizontal plane including the top surfaces of the first bit lines 128A.

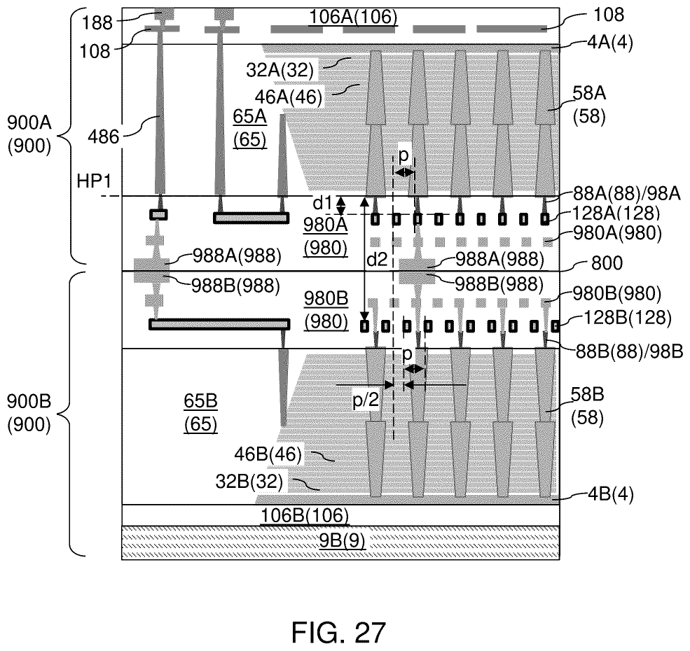

Referring to FIG. 27, the first substrate 9A can be removed from the backside of the first memory die 900A. The first substrate 9A may be removed, for example, by grinding, polishing, at least one anisotropic etch process, and/or at least one isotropic etch process. Backside bonding pads 188 can be formed within the first backside insulating layer 106A.

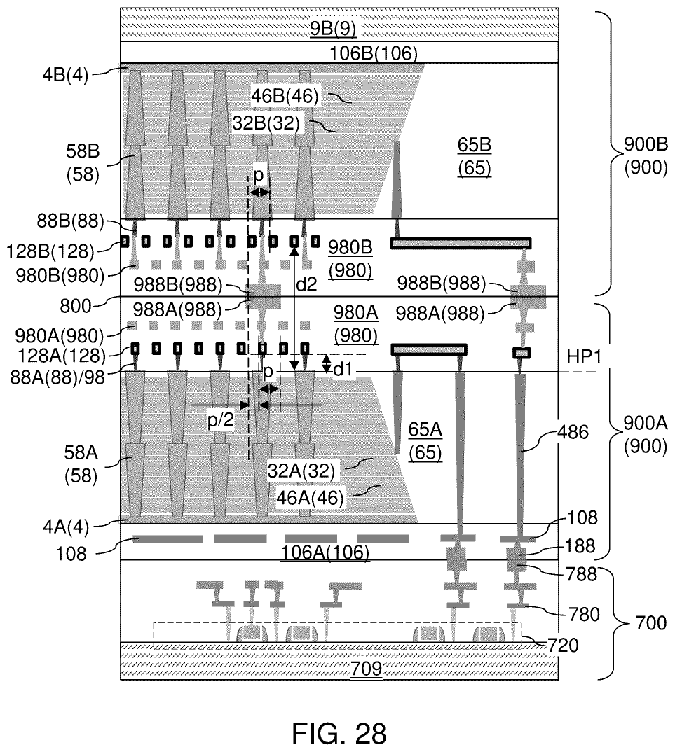

Referring to FIG. 28, a logic die 700 can be bonded to the backside of the first memory die 900A. The logic die 700 can be bonded to the first memory die 900A such that the first memory die 900A is located between the logic die 700 and the second memory die 900B. Generally, the logic die 700 comprises a driver circuit 720 configured to control operation of the first memory die 900A and the second memory die 900B.

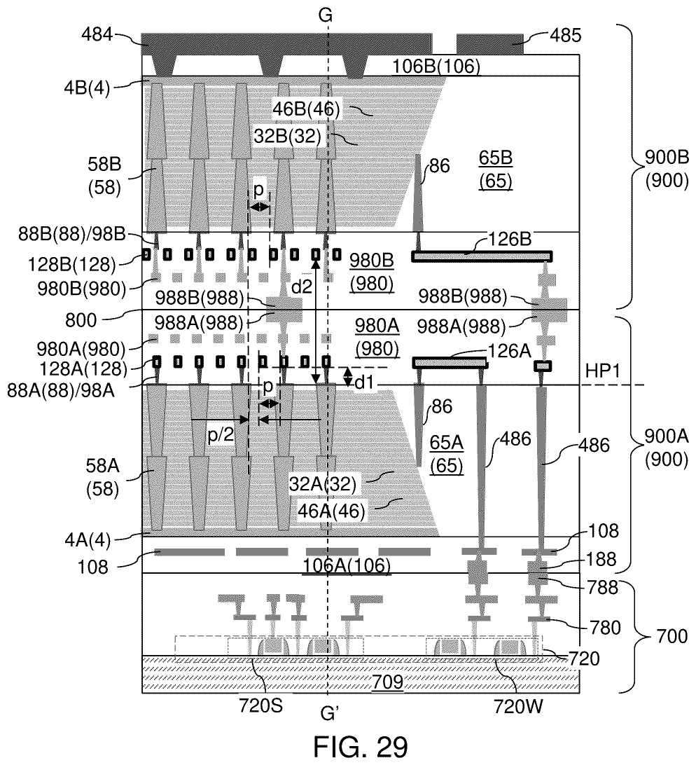

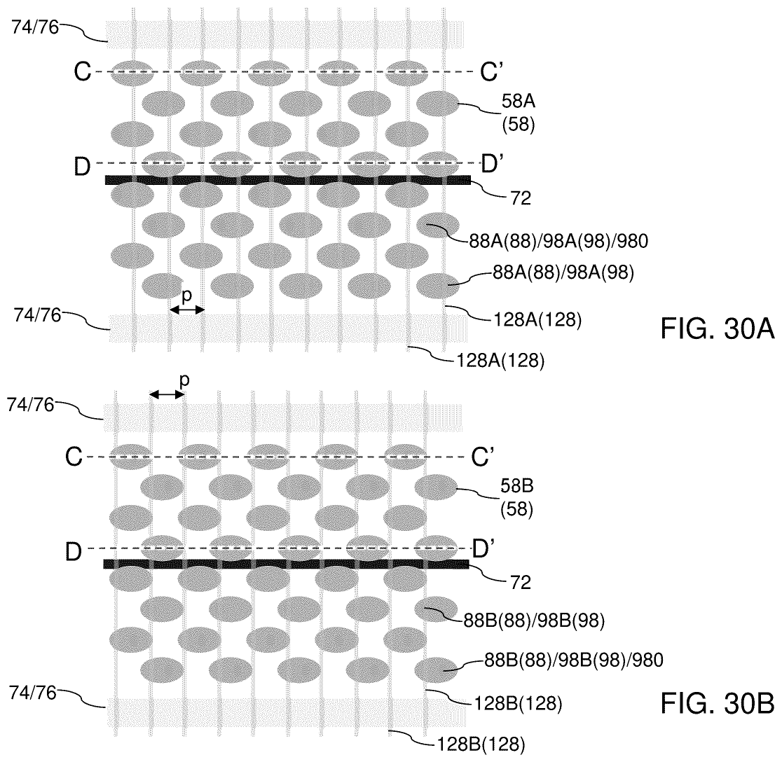

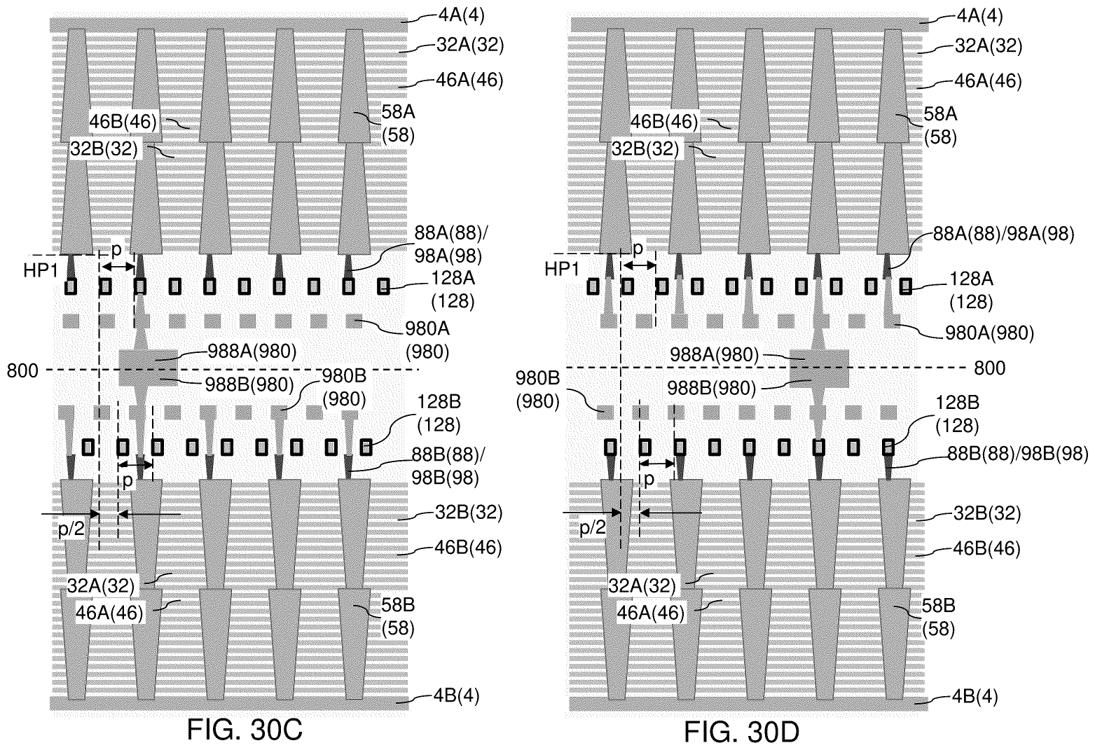

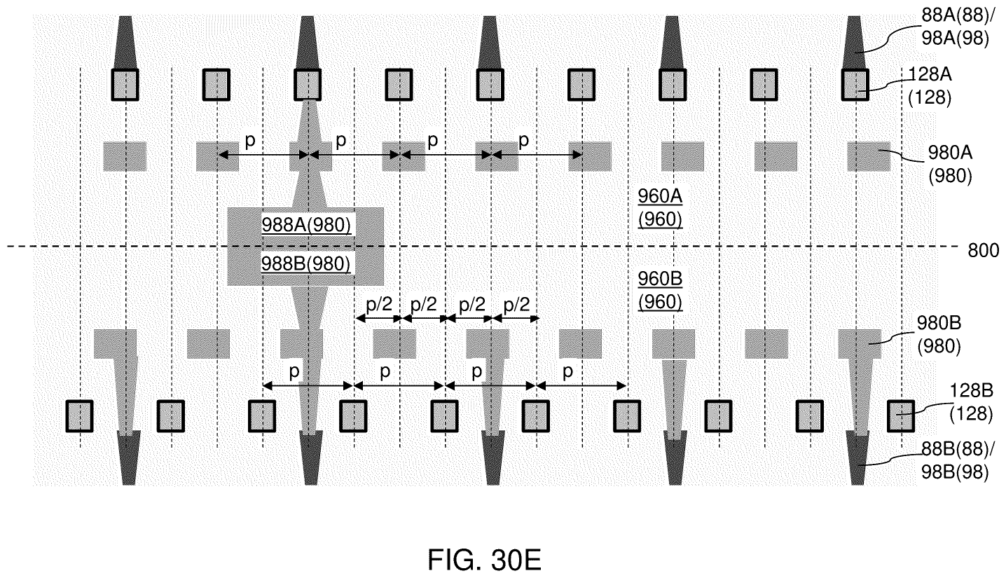

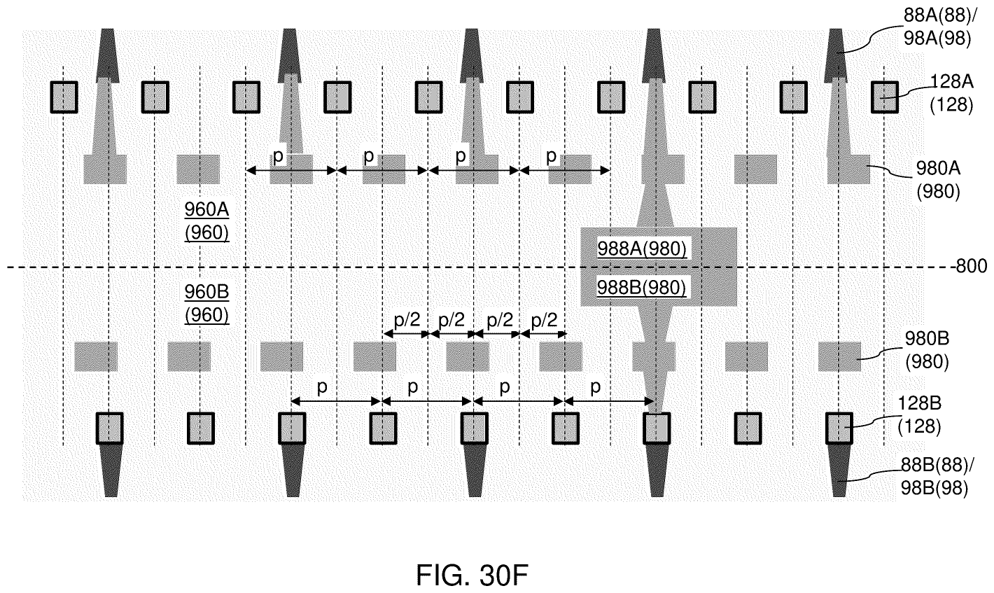

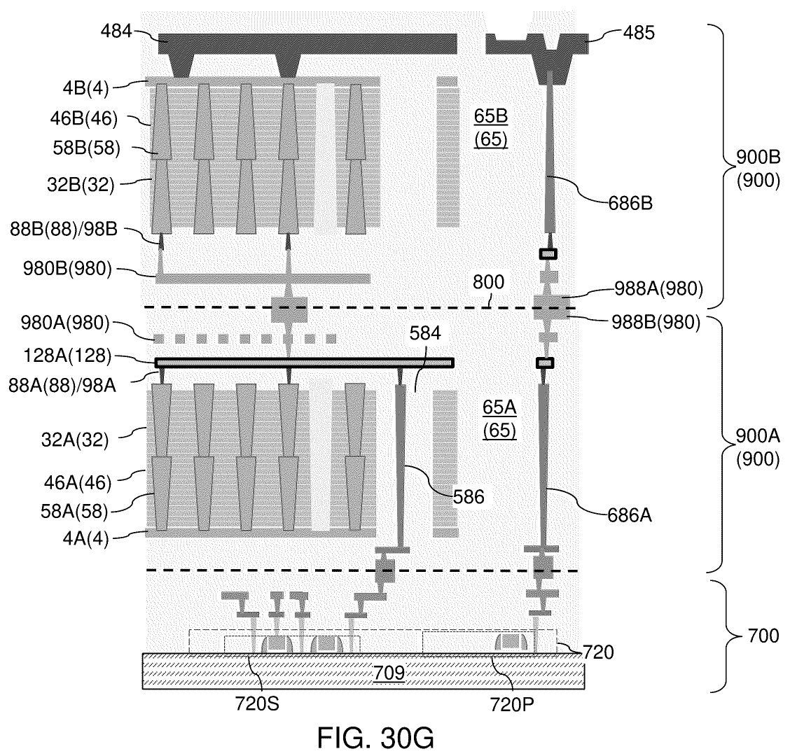

Referring to FIGS. 29 and 30A-30G, the second substrate 9B may be removed from the backside of the second memory die 900B. Backside source contact structures 484 may be formed through the second backside insulating layer 106B on the backside surface of the second source layer 4B. Backside contact pad structures 485 may be formed on the backside surface of the second backside insulating layer 106B.

The driver circuit 720 includes a word line switching circuit 720W which is electrically connected to the word lines 46 in both memory dies through connection via structures 486, layer contact via structures 86, respective bit-line-level metal lines 126A or 126B, and through bonding pads 988 for the second memory die 900B, as shown in FIG. 29. The driver circuit 720 also includes a sense amplifier circuit 720S which is electrically connected to the bit lines (128A, 128B) in both memory dies through bit line connection via structures 586, and through bonding pads 988 for the second memory die 900B, as shown in FIG. 30G. The bit line connection via structures 586 are located in dielectric filled via openings 584 which vertically extend through the first alternating stack (32A, 46A) in the first memory die 900A to the bonding interface 800 region. The driver circuit 720 also includes a peripheral circuit 720P which is electrically connected to the backside contact pad structure 485 though the peripheral connection via structures (686A, 686B) and the bonding pads 980, as shown in FIG. 30G.

Referring collectively to FIGS. 1-30G and according to various embodiments of the present disclosure, a semiconductor structure comprises: a three dimensional memory device (32, 46, 58) containing drain regions 63 having top surfaces in a first horizontal plane HP1, first bit lines (128 or 128A) electrically connected to a first subset of the drain regions 63, and second bit lines (148 or 128B) electrically connected to a second subset of the drain regions 63. The second bit lines are located above the first bit lines.

In one embodiment, the three dimensional memory device (32, 46, 58) comprises: first alternating stacks {(32, 46) or (32A, 46A)} of first insulating layers (32 or 32A) and first electrically conductive layers (46 or 46A), wherein the first alternating stacks {(32, 46) or (32A, 46A)} are laterally spaced from each other by first lateral isolation trenches 79 that laterally extend along a first horizontal direction hd1; first memory openings 49 vertically extending through the first alternating stacks {(32, 46) or (32A, 46A)}; first memory opening fill structures 58 located in the first memory openings 49, wherein each of the first memory opening fill structures 58 comprises a respective first vertical semiconductor channel 60, a respective vertical stack of first memory elements (comprising as portions of a respective memory material layer 54), and a respective first drain region 63 of the drain regions 63 contacting a first end of the respective first vertical semiconductor channel 60, and wherein the first electrically conductive layers 46A comprise first word lines of the first memory elements (as embodied as portions of a respective memory material layer 54) of the first memory opening fill structures 58.

The first bit lines (128 or 128A) extend over each of the first alternating stacks (32A, 46A) along a second horizontal direction hd2 that is perpendicular to the first horizontal direction hd1, are electrically connected to a respective first subset of the first drain regions 63, are vertically spaced by a first vertical distance d1 from a first horizontal plane HP1 including top surfaces of the first drain regions 63, and have a uniform pitch p along the first horizontal direction hd1; and second bit lines (148 or 128B) extending over the first bit lines (128 or 128A) along the second horizontal direction hd2, electrically connected to a respective second subset of the first drain regions 63, vertically spaced by a second vertical distance d2 that is greater than the first vertical distance d1 from the first horizontal plane HP1, and having the uniform pitch p along the first horizontal direction hd1.

In one embodiment, the second bit lines (148 or 128B) are laterally offset along the first horizontal direction hd1 by a lateral offset distance of p/N relative to the first bit lines (128 or 128A), wherein N is a positive integer less than 7. In one embodiment, bottom surfaces of the second bit lines (148 or 128B) are located above a horizontal plane including top surfaces of the first bit lines (128 or 128A).

In one embodiment, the semiconductor structure comprises third bit lines 168 extending over the second bit lines (148 or 128B) along the second horizontal direction hd2, electrically connected to a respective third subset of the first drain regions 63, vertically spaced by a third vertical distance d3 that is greater than the second vertical distance d2 from the first horizontal plane HP1, and having the uniform pitch p along the first horizontal direction hd1.

In one embodiment, the first bit lines (128 or 128A), the second bit lines (148 or 128B), and the first alternating stacks (32A, 46A) are located within a memory die 900; and the semiconductor structure further comprises a logic die 700 that is bonded to the memory die 900 and comprising a driver circuit 720 configured to electrically bias the word lines, the first bit lines (128 or 128A), and the second bit lines (148 or 128B). In one embodiment, the memory die 900 comprises memory-die bonding pads 988 that are embedded within memory-die dielectric material layers 960 which overlie the second bit lines (148 or 128B); and the logic die 700 comprises logic-die bonding pads 788 that are embedded within logic-die dielectric material layers, wherein the logic-die bonding pads 788 are bonded to the memory-die bonding pads.

In one embodiment, the semiconductor structure comprises a source layer 4 underlying the first alternating stacks (32A, 46A) and contacting second ends of the vertical semiconductor channels 60. In one embodiment, the semiconductor structure comprises: first. connection via structures 98 located between the first horizontal plane HP1 and a second horizontal plane HP2 including bottom surfaces of the first bit lines (128 or 128A), wherein a first subset of the first connection via structures 98 contacts a respective one of the first bit lines (128 or 128A); and second connection via structures 138 vertically extending between the second horizontal plane HP2 and a third horizontal plane HP3 including bottom surfaces of the second bit lines (148 or 128B) and located between a respective neighboring pair of first bit lines (128 or 128A). In one embodiment, the second connection via structures 138 contact top surfaces of a second subset of the first connection via structures 98; and a first subset of the second connection via structures 138 contacts bottom surfaces of the second bit lines (148 or 128B).

In one embodiment, the first bit lines 128A and the first alternating stacks (32A, 46A) are located within a first memory die 900A; and the second bit lines 128B are located within a second memory die 900B that is bonded to the first memory die 900A.

In one embodiment, the first subset of the drain regions 63 comprises a first portion of the first drain regions located in the first memory die 900A and a first portion of second drain regions located in the second memory die 900B; the second subset of the drain regions 63 comprises a second portion of the first drain regions located in the first memory die 900A and a second portion of second drain regions located in the second memory die 900B; each of the first bit lines 128A is electrically connected to plural first drain regions of the first portion of the first drain regions located in the first memory die 900A and to plural second drain regions of the first portion of the second drain regions located in the second memory die 900; and each of the second bit lines 128B is electrically connected to plural first drain regions of the second portion of the first drain regions located in the first memory die 900A and to plural second drain regions of the second portion of the second drain regions located in the second memory die 900B.

In one embodiment, the first memory die 900A comprises first bonding pads (such as first memory-die bonding pads 988A) embedded in first dielectric material layers; and the second memory die 900B comprises second bonding pads (such as second memory-die bonding pads 988B) embedded in second dielectric material layers and bonded to the first bonding pads (such as first memory-die bonding pads 988A).

In one embodiment, the semiconductor structure comprises a logic die 700 bonded to the first memory die 900A such that the first memory die 900A is located between the logic die 700 and the second memory die 900B, wherein the logic die 700 comprises a driver circuit 720 configured to control operation of the first memory die 900A and the second memory die 900B. Bit line connection via structures 586 vertically extend through dielectric filled openings 584 in at least one of the first alternating stacks (32A, 46A), and electrically connect a sense amplifier circuit portion 720S of the driver circuit 720 to the first bit lines 128A and to the second bit lines 128B.

In one embodiment, the second memory die 900B comprises: second alternating stacks (32B, 46B) of second insulating layers 32B and second electrically conductive layers 46B, wherein the second alternating stacks (32B, 46B) are laterally spaced apart from each other by second lateral isolation trenches 79; second memory openings 49 vertically extending through the second alternating stacks (32B, 46B); and second memory opening fill structures 58B located in the second memory openings 49, wherein each of the second memory opening fill structures 58 comprises a respective second vertical semiconductor channel 60, a respective vertical stack of second memory elements (as embodied as portions of a respective memory material layer 54), and a respective second drain region 63 contacting a first end of the respective second vertical semiconductor channel 60, and wherein the second electrically conductive layers 46B comprise second word lines of the second memory elements (as embodied as portions of a respective memory material layer 54) of the second memory opening fill structures 58B.

In one embodiment, the first bit lines 128A and the second bit lines 128B are vertically located between the first memory opening fill structures 58A and the second memory opening fill structures 58B.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A semiconductor structure, comprising:
a three dimensional memory device comprising drain regions having top surfaces in a first horizontal plane;
first bit lines electrically connected to a first subset of the drain regions; and
second bit lines electrically connected to a second subset of the drain regions, wherein the second bit lines are located above the first bit lines.

2. The semiconductor structure of claim 1, wherein the three dimensional memory device comprises:
first alternating stacks of first insulating layers and first electrically conductive layers, wherein the first alternating stacks are laterally spaced apart from each other by first lateral isolation trenches that laterally extend along a first horizontal direction;
first memory openings vertically extending through the first alternating stacks; and
first memory opening fill structures located in the first memory openings, wherein each of the first memory opening fill structures comprises a respective first vertical semiconductor channel, a respective vertical stack of first memory elements, and a respective first drain region of the drain regions contacting a first end of the respective first vertical semiconductor channel, and wherein the first electrically conductive layers comprise first word lines of the first memory elements of the first memory opening fill structures.

3. The semiconductor structure of claim 2, wherein:
the first bit lines extend over each of the first alternating stacks along a second horizontal direction that is perpendicular to the first horizontal direction, are electrically connected to the first subset of the first drain regions, are vertically spaced by a first vertical distance from the first horizontal plane including top surfaces of the first drain regions, and have a uniform pitch p along the first horizontal direction; and
the second bit lines extend over the first bit lines along the second horizontal direction, are electrically connected to the second subset of the first drain regions, are vertically spaced by a second vertical distance that is greater than the first vertical distance from the first horizontal plane, and have the uniform pitch p along the first horizontal direction.

4. The semiconductor structure of claim 3, wherein:
the second bit lines are laterally offset along the first horizontal direction by a lateral offset distance of p/N relative to the first bit lines, wherein N is a positive integer less than 7; and
bottom surfaces of the second bit lines are located above a horizontal plane including top surfaces of the first bit lines.

5. The semiconductor structure of claim 3, further comprising third bit lines extending over the second bit lines along the second horizontal direction, electrically connected to a third subset of the first drain regions, vertically spaced by a third vertical distance that is greater than the second vertical distance from the first horizontal plane, and having the uniform pitch p along the first horizontal direction.

6. The semiconductor structure of claim 2, wherein:
the first bit lines, the second bit lines, and the first alternating stacks are located within a memory die;
the semiconductor structure further comprises a logic die that is bonded to the memory die and comprising a driver circuit configured to electrically bias the word lines, the first bit lines, and the second bit lines;
the memory die comprises memory-die bonding pads that are embedded within memory-die dielectric material layers which overlie the second bit lines; and
the logic die comprises logic-die bonding pads that are embedded within logic-die dielectric material layers, wherein the logic-die bonding pads are bonded to the memory-die bonding pads.

7. The semiconductor structure of claim 2, further comprising:
a source layer underlying the first alternating stacks and contacting second ends of the vertical semiconductor channels;
first connection via structures located between the first horizontal plane and a second horizontal plane including bottom surfaces of the first bit lines, wherein a first subset of the first connection via structures contacts a respective one of the first bit lines; and
second connection via structures vertically extending between the second horizontal plane and a third horizontal plane including bottom surfaces of the second bit lines and located between a respective neighboring pair of first bit lines.

8. The semiconductor structure of claim 7, wherein:
the second connection via structures contact top surfaces of a second subset of the first connection via structures; and
a first subset of the second connection via structures contacts bottom surfaces of the second bit lines.

9. The semiconductor structure of claim 2, wherein:
the first bit lines and the first alternating stacks are located within a first memory die; and
the second bit lines are located within a second memory die that is bonded to the first memory die.

10. The semiconductor structure of claim 9, wherein:
the first subset of the drain regions comprises a first portion of the first drain regions located in the first memory die and a first portion of second drain regions located in the second memory die;
the second subset of the drain regions comprises a second portion of the first drain regions located in the first memory die and a second portion of second drain regions located in the second memory die;
each of the first bit lines is electrically connected to plural first drain regions of the first portion of the first drain regions located in the first memory die and to plural second drain regions of the first portion of the second drain regions located in the second memory die; and
each of the second bit lines is electrically connected to plural first drain regions of the second portion of the first drain regions located in the first memory die and to plural second drain regions of the second portion of the second drain regions located in the second memory die.

11. The semiconductor structure of claim 9, wherein:
the first memory die comprises first bonding pads embedded in first dielectric material layers; and
the second memory die comprises second bonding pads embedded in second dielectric material layers and bonded to the first bonding pads.

12. The semiconductor structure of claim 9, further comprising:
a logic die bonded to the first memory die such that the first memory die is located between the logic die and the second memory die, wherein the logic die comprises a driver circuit configured to control operation of the first memory die and the second memory die; and
bit line connection via structures which vertically extend through dielectric filled openings in at least one of the first alternating stacks, and electrically connect a sense amplifier circuit portion of the driver circuit to the first bit lines and to the second bit lines.

13. The semiconductor structure of claim 9, wherein the second memory die comprises:
second alternating stacks of second insulating layers and second electrically conductive layers, wherein the second alternating stacks are laterally spaced apart from each other by second lateral isolation trenches;
second memory openings vertically extending through the second alternating stacks; and
second memory opening fill structures located in the second memory openings, wherein each of the second memory opening fill structures comprises a respective second vertical semiconductor channel, a respective vertical stack of second memory elements, and a respective second drain region contacting a first end of the respective second vertical semiconductor channel, and wherein the second electrically conductive layers comprise second word lines of the second memory elements of the second memory opening fill structures.

14. The semiconductor structure of claim 13, wherein the first bit lines and the second bit lines are vertically located between the first memory opening fill structures and the second memory opening fill structures.

15. A method of forming a semiconductor structure, comprising:
providing a first memory die that comprises first alternating stacks of first insulating layers and first electrically conductive layers, first memory openings vertically extending through the first alternating stacks, first memory opening fill structures located in the first memory openings, and first bit lines, wherein the first alternating stacks are laterally spaced apart from each other by first lateral isolation trenches that laterally extend along a first horizontal direction, wherein each of the first memory opening fill structures comprises a respective first vertical semiconductor channel, a respective vertical stack of first memory elements, and a respective first drain region contacting a first end of the respective first vertical semiconductor channel, wherein the first electrically conductive layers comprise first word lines of the first memory elements of the first memory opening fill structures, and wherein the first bit lines extend over each of the first alternating stacks along a second horizontal direction that is perpendicular to the first horizontal direction, are electrically connected to a respective first subset of the first drain regions, are vertically spaced by a first vertical distance from a first horizontal plane including top surfaces of the first drain regions, and have a uniform pitch p along the first horizontal direction;
providing an additional semiconductor die that comprises second bit lines having a pitch that equals the uniform pitch p; and
bonding the additional semiconductor die to the first memory die such that the second bit lines extend over the first bit lines along the second horizontal direction, are electrically connected to a respective second subset of the first drain regions, are vertically spaced by a second vertical distance that is greater than the first vertical distance from the first horizontal plane, and have the uniform pitch p along the first horizontal direction.

16. The method of claim 15, wherein the additional semiconductor die comprises a second memory die that comprises:
second alternating stacks of second insulating layers and second electrically conductive layers, wherein the second alternating stacks are laterally spaced apart from each other by second lateral isolation trenches;
second memory openings vertically extending through the second alternating stacks; and
second memory opening fill structures located in the second memory openings, wherein each of the second memory opening fill structures comprises a respective second vertical semiconductor channel, a respective vertical stack of second memory elements, and a respective second drain region contacting a second end of the respective second vertical semiconductor channel, and wherein the second electrically conductive layers comprise second word lines of the second memory elements of the second memory opening fill structures.

17. The method of claim 16, wherein:
each of the first bit lines is electrically connected to a respective first subset of the second drain regions upon bonding the second memory die to the first memory die; and
each of the second bit lines is electrically connected to a respective second subset of the second drain regions.

18. A method of forming a semiconductor structure, comprising:
forming an assembly of first alternating stacks of first insulating layers and first electrically conductive layers and first memory opening fill structures vertically extending through the first alternating stacks, wherein the first alternating stacks are laterally spaced apart from each other by first lateral isolation trenches that laterally extend along a first horizontal direction, wherein each of the first memory opening fill structures comprises a respective first vertical semiconductor channel, a respective vertical stack of first memory elements, and a respective first drain region contacting a first end of the respective first vertical semiconductor channel, and wherein the first electrically conductive layers comprise first word lines of the first memory elements of the first memory opening fill structures;
forming first bit lines extending over each of the first alternating stacks along a second horizontal direction that is perpendicular to the first horizontal direction, wherein the first bit lines are electrically connected to a respective first subset of the first drain regions, are vertically spaced by a first vertical distance from a first horizontal plane including top surfaces of the first drain regions, and have a uniform pitch p along the first horizontal direction; and
forming second bit lines extending over the first bit lines along the second horizontal direction, wherein the second bit lines are electrically connected to a respective second subset of the first drain regions, are vertically spaced by a second vertical distance that is greater than the first vertical distance from the first horizontal plane, and have the uniform pitch p along the first horizontal direction.

19. The method of claim 18, wherein the second bit lines are laterally offset along the first horizontal direction by a lateral offset distance of p/N relative to the first bit lines, wherein N is a positive integer less than 7.

20. The method of claim 18, wherein:
the assembly, the first bit lines, and the second bit lines are formed in a first memory die; and
the method further comprises bonding a logic die to the memory die, wherein the logic die comprises a driver circuit configured to electrically bias the word lines, the first bit lines, and the second bit lines.
